(19) United States
(12) Patent Application Publication
(10) Pub. No.: US 2026/0370383 A1
(43) Pub. Date: Nov. 19, 2026

(54) METHODS, APPARATUS, AND SYSTEMS FOR POLAR CODE CONSTRUCTION

(71) Applicant: Huawei Technologies Co., Ltd., Shenzhen (CN)

(72) Inventors: Huazi Zhang, Zhejiang (CN); Jianglei Ma, Ottawa (CA); Wen Tong, Ottawa (CA)

(21) Appl. No.: 19/699,746

(22) Filed: Jun. 5, 2026

Related U.S. Application Data
(63) Continuation of application No. PCT/CN2024/079026, filed on Feb. 28, 2024.
(60) Provisional application No. 63/607,968, filed on Dec. 8, 2023.

(51) Int. Cl. H04L 1/00

(52) U.S. Cl. CPC H04L 1/0057

(57) ABSTRACT

Input bits are encoded by a polar code to obtain encoded bits. The polar code provides or includes bit indices for placing bit values before encoding. The bit indices include a first set of bit indices for values of the input bits and a second set of bit indices for a predetermined bit value. Each bit index of the first set or the second set is selected from one of multiple ordered subsequences of bit indices. The ordered subsequences together include all of the bit indices of the polar code. The selection of each bit index from an ordered subsequence is based on an order of the bit indices in an ordered sequence that includes all of the bit indices.

### CROSS-REFERENCE TO RELATED APPLICATION

The present application is a continuation of International Patent Application PCT/CN2024/079026, filed on Feb. 28, 2024, which claims the benefit of U.S. Patent Application Ser. No. 63/607,968, entitled “METHODS, APPARATUS, AND SYSTEM FOR POLAR CODE CONSTRUCTION”, filed on Dec. 8, 2023. The entire contents of the aforementioned applications are hereby incorporated by reference.

### TECHNICAL FIELD

The present application relates to coding, and in particular to construction of polar codes.

### BACKGROUND

In wireless communications, channel quality is constantly changing due to the fading effects at both fast and slow scale. Accordingly, channel coding has always been designed to adapt to the channel states. Modulation coding scheme (MCS) adaptation is a powerful method to combat varying channel states, in which the modulation order and code length and coding rate can be changed in real time. Therefore, it requires that a channel coding scheme can flexibly change the code length and code rate in a fine-grained way, and at the same time achieve good error correction performance in all possible configurations. This fine-grained flexibility of channel codes is one of the most challenging problem for engineers in this domain.

At the same time, the complexity of both encoding and decoding algorithms need to be sufficiently low. In hardware, complexity can be evaluated through measuring chip area and energy efficiency. They are related to algorithmic complexity, but are more closely related to hardware cost and battery life. Therefore, there exists a desire to reduce implementation complexity when designing coding schemes.

Future communication systems, such as so-called sixth-generation (6G) systems, may aim to support several challenging scenarios, including for example immersive communication, massive communication, and hyper reliable and low-latency communication. The KPIs that are related to channel coding include coding gain, reliability, throughput, latency and their tradeoffs. For example, the throughput target of 6G may reach above 1 Tbps, and the energy efficiency target may decrease to 1 pJ/bit. Meanwhile, a coding scheme supporting flexible rate matching and IR-HARQ schemes is also beneficial. Accordingly, it is desirable yet challenging to design a code ensemble to fulfill all these KPIs and capabilities.

### SUMMARY

Some embodiments of the present disclosure include methods to select information bit positions, frozen bit positions, parity-check bit positions or CRC bit positions for rate matched polar codes. The methods also support IR-HARQ retransmission for polar codes.

Some embodiments of the present disclosure may include the following objectives: to obtain a stable performance under a wide range of code lengths and rates; to support multiple transmissions and retransmissions, for example, with multiple redundancy versions.

Methods in accordance with embodiments of the present disclosure may include one or more of the following features: methods to select information/frozen/PC/CRC bit positions according to a nested reliability sequence; methods to adjust code rates of certain subblocks in a polar code according to a nested reliability sequence.

Some embodiments of the present disclosure include one or more of the following features, which can be separately adopted, or work together as a complete solution.

Some embodiments of the present disclosure include methods to select information bit positions (and other bit positions) to support flexible code length and rates, and also to support potential IR-HARQ retransmissions. Some embodiments include two aspects or parts. The first part relates to selecting information bit positions considering rate matching. The second part relates to methods to adjust the code rate of certain blocks.

According to an aspect of the present disclosure, a method involves encoding input bits by a polar code to obtain a number of encoded bits, and outputting the encoded bits. The polar code includes or provides multiple bit indices for placing bit values before the encoding, and the bit indices include a first set of bit indices for values of the input bits and a second set of bit indices for a predetermined bit value. Each bit index of the first set or the second set is selected, from an ordered subsequence of multiple ordered subsequences of bit indices that together include the multiple bit indices, based on an order of the bit indices in an ordered sequence that includes all of the bit indices.

Another method disclosed herein involves obtaining multiple bit indices for placing bit values for encoding by a polar code to obtain a number of encoded bits, encoding input bits by the polar code to obtain the number of encoded bits, and outputting the encoded bits. The bit indices include a first set of bit indices for values of the input bits and a second set of bit indices for a predetermined bit value, and each bit index of the first set or the second set is selected from an ordered subsequence that is one of multiple ordered subsequences of bit indices. The multiple ordered subsequences together include all of the bit indices, and each bit index of the first set or the second set is selected based on an order of the bit indices in an ordered sequence that includes all of the bit indices.

According to another example herein, a method may involve receiving a number of encoded bits encoded by a polar code, and decoding the encoded bits to obtain decoded input bits. The polar code includes or provides multiple bit indices for placing bit values for encoding. The bit indices include a first set of bit indices for values of input bits and a second set of bit indices for a predetermined bit value Each bit index of the first set or the second set is selected, from an ordered subsequence of multiple ordered subsequences of bit indices that together include the multiple bit indices, based on an order of the bit indices in an ordered sequence that includes all of the bit indices.

Yet another method disclosed herein involves receiving a number of encoded bits encoded by obtaining bit indices for placing bit values for encoding by a polar code, and decoding the encoded bits to obtain decoded input bits. The bit indices include a first set of bit indices for values of input bits and a second set of bit indices for a predetermined bit value, and each bit index of the first set or the second set is selected, from an ordered subsequence of multiple ordered subsequences of bit indices that together include all of the bit indices, based on an order of the bit indices in an ordered sequence that includes all of the bit indices.

Apparatus embodiments are also disclosed.

An apparatus may include an encoder for encoding input bits by a polar code to obtain a number of encoded bits, and an interface, coupled to the encoder, for outputting the encoded bits.

Another example provided herein relates to an apparatus that includes an interface for receiving a number of encoded bits encoded by a polar code, and a decoder, coupled to the interface, for decoding the encoded bits to obtain decoded input bits.

In these apparatus examples, and others herein, the polar code includes or provides bit indices for placing bit values before encoding, and the bit indices include a first set of bit indices for values of input bits and a second set of bit indices for a predetermined bit value. Each bit index of the first set or the second set is selected, from an ordered subsequence of multiple ordered subsequences of bit indices that together include the plurality of bit indices, based on an order of the bit indices in an ordered sequence that includes all of the bit indices.

According to another example herein, an apparatus includes: an encoder for obtaining bit indices of a polar code, and for encoding bit values placed on the bit indices by the polar code to obtain a number of encoded bits; and an interface, coupled to the encoder, for outputting the encoded bits.

Yet another example herein relates to an apparatus that includes: an interface for receiving a number of encoded bits that have been encoded by obtaining bit indices for placing bit values for encoding by a polar code; and a decoder, coupled to the interface, for decoding the encoded bits to obtain decoded input bits.

In these apparatus examples, the bit indices include a first set of bit indices for values of input bits and a second set of bit indices for a predetermined bit value, and each bit index of the first set or the second set is selected, from an ordered subsequence of multiple ordered subsequences of bit indices that together include all of the bit indices, based on an order of the bit indices in an ordered sequence that includes all of the bit indices.

In other apparatus embodiments, an apparatus may include a processor configured to cause the apparatus to perform any of the methods as disclosed herein.

An apparatus may include a processor and a non-transitory computer readable storage medium that is coupled to the processor and stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

A system is also disclosed, and may include a first communication device configured to transmit a number of encoded bits that have been encoded by a polar code, and a second communication device configured to configured to receive the encoded bits from the first communication device, and to decode the encoded bits to obtain decoded input bits. The polar code includes or provides bit indices for placing bit values before encoding, and the bit indices include a first set of bit indices for values of input bits and a second set of bit indices for a predetermined bit value. Each bit index of the first set or the second set is selected, from an ordered subsequence of multiple ordered subsequences of bit indices that together include all of the bit indices, based on an order of the bit indices in an ordered sequence that includes all of the bit indices.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a trellis graph illustrating an example of a polar code.

FIG. 6A illustrates puncturing and shortening of an interleaving pattern.

FIG. 6B illustrates puncturing and shortening with a cyclic buffer.

FIG. 7 illustrates retransmissions to which incremental freezing may be applied.

FIG. 8A illustrates polar encoding of an example initial transmission and an example retransmission.

FIG. 8B illustrates a polar transform matrix representation of three transmissions with effective code lengths M₁=8, M₂=12, M₃=16.

FIG. 9 illustrates an example general procedure.

FIG. 10 illustrates an example of constructing an N=16, K=8 polar code, by dividing into two subblocks with a threshold T=7.

FIG. 11 illustrates an example of a code constructed using interleaved bit indices.

FIG. 12 provides a graphical illustration of threshold determination according to an embodiment.

FIG. 13 illustrates an example of a hierarchical or recursive method of constructing a polar code.

FIG. 14 illustrates an example of constructing an N=16, K=8 polar code, by dividing into two subblocks with multiple thresholds.

FIG. 15 illustrates more general example methods according to embodiments.

FIG. 16 illustrates an apparatus according to an embodiment.

### DETAILED DESCRIPTION OF THE ILLUSTRATIVE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

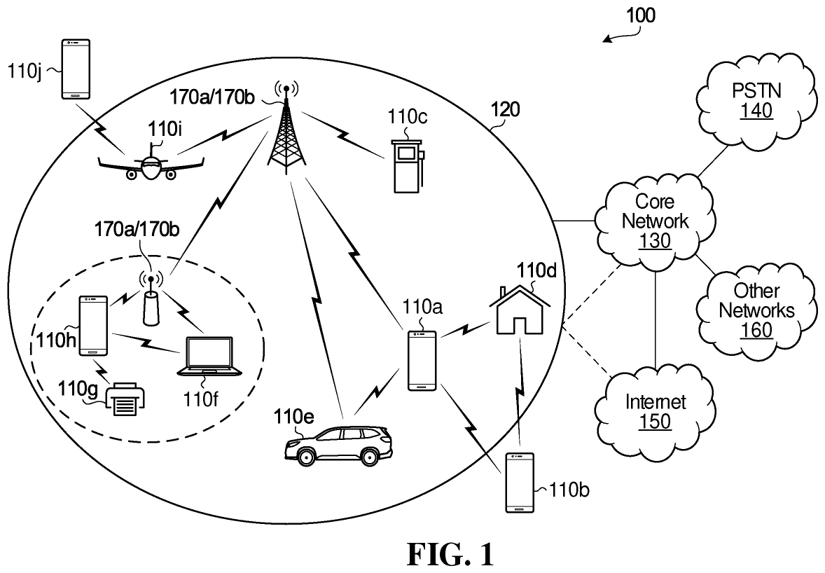

Referring to FIG. 1, as an illustrative example without limitation, a simplified schematic illustration of a communication system is provided. The communication system 100 comprises a radio access network 120. The radio access network 120 may be a next generation (for example sixth generation (6G) or later) radio access network, or a legacy (for example 5G, 4G, 3G or 2G) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

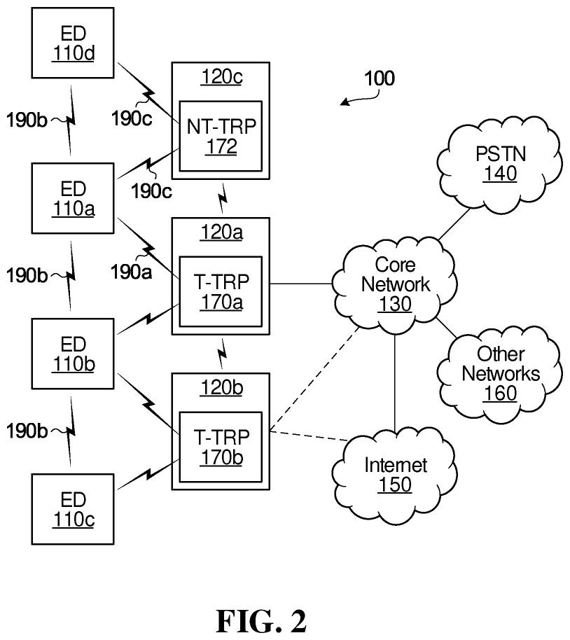

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, and so on. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, and so on). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

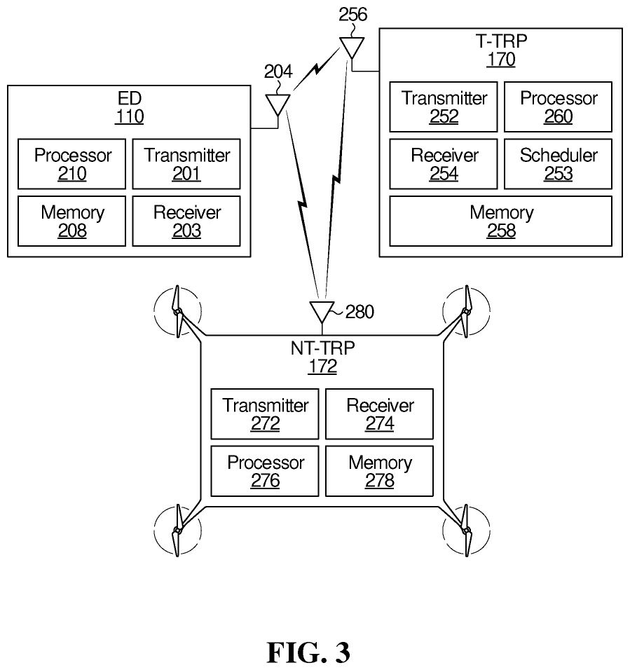

FIG. 3 illustrates another example of an ED 110 and a base station 170a, 170b and/or 172. The ED 110 is used to connect persons, objects, machines, and so on. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, and so on.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, and so on), an industrial device, or an apparatus in (for example communication module, modem, or chip) or comprising the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (that is, established, activated, or enabled), turned-off (that is, released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, for example as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (for example, a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, and so on.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (for example by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, for example beam angle information (BAI), received from the T-TRP 170. In some embodiments, the processor 210 may perform operations relating to network access (for example initial access) and/or downlink synchronization, such as operations relating to detecting a synchronization sequence, decoding and obtaining the system information, and so on. In some embodiments, the processor 210 may perform channel estimation, for example using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (for example in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (for example a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, for example through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (for example multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (for example initial access) and/or downlink synchronization, such as generating the content of synchronization signal blocks (SSBs), generating the system information, and so on. In some embodiments, the processor 260 also generates an indication of beam direction, for example BAI, which may be scheduled for transmission by a scheduler 253. The processor 260 performs other network-side processing operations described herein, such as determining the location of the ED 110, determining where to deploy the NT-TRP 172, and so on. In some embodiments, the processor 260 may generate signaling, for example to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, for example a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (for example, higher than physical layer) packet transmitted in a physical layer data channel, for example in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (for example, “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, for example in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (for example, a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (for example MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (for example BAI) received from the T-TRP 170. In some embodiments, the processor 276 may generate signaling, for example to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, for example in the memory 278. Alternatively, some or all of the processor 276, the processing components of the transmitter 272, and the processing components of the receiver 274 may be implemented using dedicated circuitry, such as a programmed FPGA, a hardware accelerator (for example, a GPU or AI accelerator), or an ASIC. In some embodiments, the NT-TRP 172 may actually be a plurality of NT-TRPs that are operating together to serve the ED 110, for example through coordinated multipoint transmissions.

The T-TRP 170, the NT-TRP 172, and/or the ED 110 may include other components, but these have been omitted for the sake of clarity.

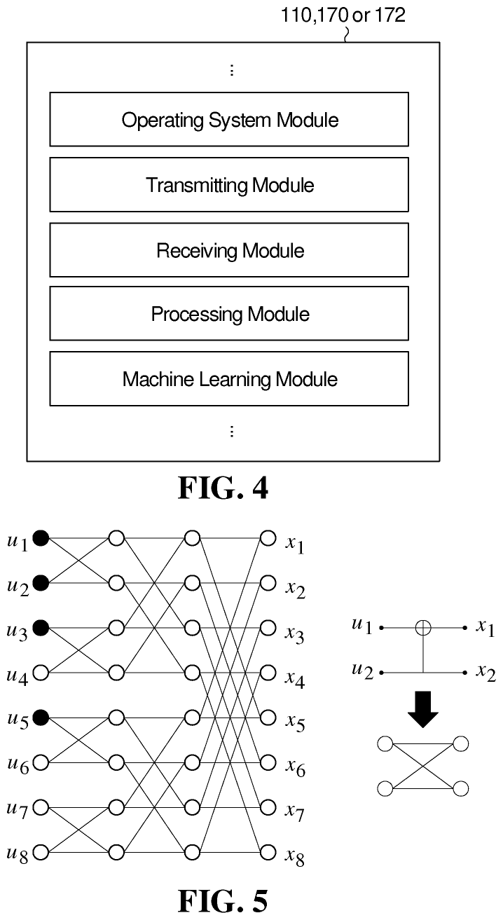

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit includes a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

The channel coding module in communications systems encode K source bits into N code bits to provide error correction capability against adversary channel conditions such as noise and interference. The code rate is R=K/N. In practice, the code rate R is selected according to channel quality.

Polar codes are capacity-achieving codes and thus a great breakthrough in coding theory. As code length approaches infinity, the synthesized channels (also known as subchannels, which are created by or associated with the polar code) become either noiseless or pure noise. The noiseless subchannels are utilized to transport information, and their proportion is proven to achieve the channel capacity defined by Shannon. A polarization phenomenon occurs under successive cancellation (SC) or SC-based decoding, which has a relatively low complexity.

Low-density parity-check (LDPC) codes are capacity-approaching codes. LDPC codes may be defined by a parity-check matrix, which typically has far more zeros than ones—in other words, having low density. By properly designing the positions of the ones in the matrix, the decoding performance can be improved. Although LDPC codes can theoretically be viewed as a type of random code, certain structures, whether conceptual or physical, can facilitate the hardware implementation of LDPC encoders and decoders. A “Quasi-cyclic” (QC) structure is an example structure that may improve performance and/or implementation complexity. A QC-LDPC scheme first defines a smaller base matrix or base graph (BG), and then performs a “lifting” operation that replaces the ones in the base matrix or graph with a cyclic shifted version of an identity matrix.

Rate matching is performed after channel encoding, by either puncturing/shortening or repeating some code bits. The purpose of this operation is to obtain a code bit sequence of desired length for transmission over limited channel resources.

Channel interleaving is applied after channel encoding and rate matching by permuting the code bits. The purpose is to provide stable or superior performance under high-order modulation or in a fading channel.

Hybrid automatic repeat request (HARQ) is a mechanism to provide reliable wireless transmission. It combines forward error correction (FEC) and automatic repeat request (ARQ). In HARQ, the initial transmission is a FEC code word with means (such as CRC bits) to support error detection at the receiver. If a decoding error is detected, the receiver will send back a negative acknowledgment (NACK) signaling to inform the transmitter of the error, and request a retransmission. The retransmitted bits can be directly selected from the initially transmitted bits, or incrementally generated code bits which form a longer code word with the initially transmitted bits. The former approach is called chase-combining HARQ (CC-HARQ) and the latter approach is called incremental-redundancy HARQ (IR-HARQ). Typically, IR-HARQ outperforms CC-HARQ with the additional coding gain from incremental redundancy.

Polar codes belong to the class of linear block codes. For a polar code of length N, its generator matrix is G_{N}, and its encoding process is

$${x}_{1}^{N} = {u}_{1}^{N} {G}_{N} ,$$

where

$${u}_{1}^{N} = [ {u}_{1} , {u}_{2} , … , {u}_{N} ]$$

is the binary information vector,

$${x}_{1}^{N} = [ {x}_{1} , {x}_{2} , … , {x}_{N} ]$$

is the binary code vector. The N×N binary matrix

$${G}_{N} = {F}_{2}^{⊗ n} ,$$

where

$${F}_{2} = [ \begin{matrix}1 & 0 \\ 1 & 1\end{matrix} ]$$

is the polarization kernel matrix, n=log₂ N, and ⊗ is Kronecker product.

Typically, there are K information bits to be encoded into N code bits. Accordingly, the inequality K<N is given to obtain a code rate R=K/N<1. That implies only part of u₁^{N} is used to carry information bits, and the rest are typically called frozen bits. Denote by I the information bit set (or information set), and F the frozen bit set (or frozen set), respectively. Sometimes, there is an additional PC bit set, denoted by P. The frozen bits are known (usually all zeros, but may also be other known values or sequences) before decoding, so they do not carry any payload information. The PC bits are parity-check bits generated from a subset of information bits. Therefore, the PC bits are known once the associated information bits are decoded. The decoding of polar codes attempts to recover all information bits.

The transmitted code length M may not always be the power of 2, that is, M<N. In practice, puncturing and shortening are used to reduce transmitted code bits from N to M. For convenience, the present disclosure hereinafter refers to N as the mother code length, and M as the code length. In particular, punctured bits are non-transmitted bits unknown to the decoder, but shortened bits are non-transmitted bits known to the decoder (usually all zeros).

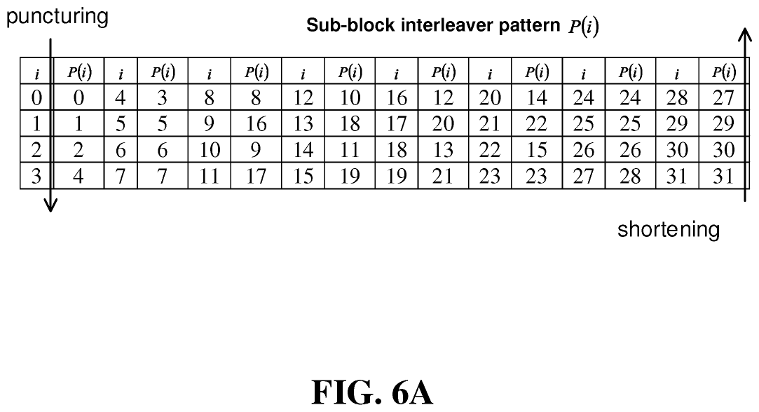

An example of a polar code with N=8, K=4 is shown in the trellis graph in FIG. 5. Each “butterfly” in the graph represents a polarization, that is,

$${x}_{1}^{2} = {u}_{1}^{2} [ \begin{matrix}1 & 0 \\ 1 & 1\end{matrix} ] .$$

In this example, the information set is I={u₄, u₆, u₇, u₈}, and the frozen set is F={u₁, u₂, u₃, u₅}.

In FIG. 5, the unshaded circles at the left represent the information set I={u₄, u₆, u₇, u₈}, and the shaded circles represent the frozen set F={u₁, u₂, u₃, u₅}.

The input vector u at the left in FIG. 5 and the code vector x at the right in FIG. 5 each include a number of bit positions. The bit positions in the input vector are indexed by respective bit indices, and bit values are placed on or at those bit indices or bit positions for encoding. These bit indices or bit positions are also sometimes referred to as bit channels or subchannels. Placing bit values on bit indices as disclosed herein may also be referred to in other ways, such as placing bits or bit values on or at bit indices, bit positions, bit channels, or subchannels; or assigning bit values or bits to bit indices, bit positions, bit channels, or subchannels. Other terminology may be used to express how bit values or bits are provided as inputs to encoding.

In this way, a polar code may be considered as providing or comprising bit indices, bit positions, bit channels, or subchannels for bit values. Those bit indices, bit positions, bit channels, or subchannels are not necessarily only for bits that are to be encoded. For example, the u vector elements u₁, . . . u_{N} are also referenced in decoding, and therefore bit values that are decoded may similarly be associated with bit indices, bit positions, bit channels, or subchannels.

On the right side in FIG. 5, the code vector x also includes a number of elements that are in or at bit positions or bit indices. A bit value on the i-th bit index in the input vector u has some effect on multiple code bits in the code vector x, but the bit value on the i-th bit index in the input vector u is the primary contributor to the value of the code bit on the corresponding i-th bit index in the code vector x. In this sense, for a polar code, input vector bit indices or bit positions may be considered to correspond to, or be associated with or related to, code vector bit indices or bit positions. This is the case for polar codes, and there may be different input/code bit correspondence, relationships, or associations for other types of codes.

Regarding encoding, the process of encoding may be expressed in any of various ways. For example, encoding may be described as encoding bits to obtain encoded bits or to generate encoded bits. The above-referenced encoding process

$${x}_{1}^{N} = {u}_{1}^{N} {G}_{N} ,$$

for example, may be expressed as generating or otherwise obtaining an encoding input (the input vector u in this example) that includes bits or bit values for encoding, to obtain or generate a number of encoded bits (the code vector x in this example).

The bit values of elements in the input vector u, from an encoding perspective, may be referred to as values or bits to be encoded, or as values or bits for encoding, for example. Blocks of bits or bit values for encoding are also sometimes referred to as code blocks. The bit values of elements in the code vector x may be referred to as encoded bits, coded bits, or code bits, and a block of such bits may be referred to as a codeword, for example.

From a decoding perspective, decoding may be referred to as decoding encoded bits, a codeword, or a code, or as decoding, obtaining, or recovering bits or bit values (that were encoded), from the encoded bits, a codeword, or a code, for example. The bit values of elements in the vector u, in the context of decoding, may be referred to as decoded or recovered bits or bit values.

Successive cancellation (SC) is the basic decoding algorithm for polar codes, where all the frozen bits and information bits are decoded sequentially, that is, bit by bit. The preceding bits are typically always decoded first.

By convention, the decoding order is the natural order of the polar code bit indices on bit values are placed. Thus, this decoding order is known as “natural order”. Preceding bits in the natural order are always decoded first, before decoding a current bit.

Successive cancellation list (SCL) is an enhanced decoding algorithm for polar codes, where multiple (for example, a number L) SC decoding instances are executed. Each instance is called a “decoding path”. When decoding each binary bit, both “0” and “1” branches are extended to each path, creating 2L paths. Then, all 2L paths are compared, where the most likely L paths are kept, and the least likely L paths are discarded (or pruned). These path extension and pruning operations are performed during decoding of every information bit, until all information bits are decoded. At last, the most likely path is selected as the decoding output.

CRC-aided successive cancellation list (CA-SCL) works almost the same as SCL, except that in the last step, the most likely path that passes CRC check is selected as the decoding output.

Parity-check successive cancellation list (PC-SCL) works almost the same as SCL, except that when decoding parity-check (PC) bits, the parity check value of associated preceding bits is used as the bit decision result. PC bits may be considered a type of bit in addition to frozen bits and information bits.

Low Density Parity Check (LDPC) code is a channel coding scheme capable of achieving performance that approaches the Shannon limit, and furthermore features good overall performance and low complexity.

The LDPC code is encoded through a parity-check matrix. One class of LDPC code has a particular structure known as quasi-cyclic (QC). In a QC-LDPC code, a shifting value of each block is designed to avoid a bad structure such as a short circle, and improve a code distance. Decoding algorithms for LDPC codes include Min-Sum (MS) and Belief Propagation (BP). In terms of decoding performance, the BP decoding algorithm is better, but it has a large amount of information storage and a complex computation overhead, which is not convenient to hardware implementation. Therefore, Offset-MS and Normalized-MS decoding algorithms are used in realistic communication systems. An example LDPC code implementation extends the “1” in the basic graph (BG) by a square matrix, which is a cyclic shifted version of an identity matrix. The BG of QC-LDPC code can be defined by BG=(X, Y, F), where X corresponds to a variable, Y corresponds to a check equation, and Fis its edge connections. The Tanner graph is obtained after QC lifting with an expansion factor Z_{c}. That is, a bipartite graph G=(V, C, E), where Vis a variable node, C is a check node, E is a connected edge, and a corresponding parity matrix column quantity N=|V|=Z_{c} |X|. The quantity of rows of the check matrix M=|C|=Z_{c} |Y|, and a quantity of non-zero elements of the check matrix is |E|=Z|F|.

In an example, LDPC payloads include information block lengths ranging from 1 to 8448. The LDPC code implementation includes two parity-check matrices: BG1 and BG2. The same base graph, lifted by different lifting sizes, can adapt to a wide set of different code rates and lengths. This flexible implementation can be achieved, for example, by storing the Lifting Size and Shifting Value lists in the look-up tables, and then performing rate matching and IR-HARQ based on the tables.

In an example rate matching scheme for LDPC codes, a codeword before rate matching (referred as a mother codeword) includes three disjoint portions or parts, that is, systematic bits, core parity check bits and extended parity check bits. Four different redundancy versions (RVs) including RV0, RV1, RV2 and RV3 are generated from the mother codeword after rate matching. In an initial transmission, RV0 is normally selected; in RV0, most of the systematic bits are included in the set of coded bits. Depending on the effective code rate, part of the core parity bits or all of the core parity check bits and extended parity bits are included in RV0. As a result, RV0 has the highest self-decodable ability among all RVs (that is, RV0 can be self-decodable at highest code rate). In a retransmission, the transmitter may select RV1, RV2 or RV3. In this particular example, only RV3 is self-decodable, while RV1 and RV2 are not self-decodable at high code rate. At some code rates, RV1 and RV2 may only include parity check bits, resulting in unsuccessful decoding at the receiver.

Rate-compatible polar coding is a desirable technology for wireless applications. In one example of polar code rate matching, a combination of puncturing, shortening and repetition is used together with a fixed reliability sequence to balance performance and complexity. In particular, subblock-wise interlacing and interleaving is used for both puncturing and shortening. The puncturing and shortening patterns are symmetric.

With mother code length N, and code length M, the specific rate matching scheme used is:
Repetition, when M>N;
Puncturing, when K/M≤ 7/16;
Shortening, when K/M> 7/16.

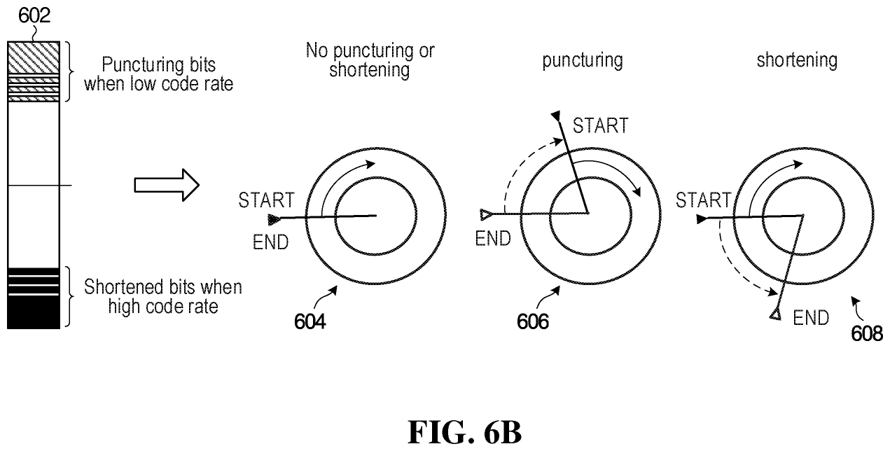

FIG. 6A is a diagram based on a table reproduced from a 3GPP standard specification. The diagram illustrates an example interleaving scheme. A subblock-wise interleaving is performed before puncturing and shortening. The interleaver partitions the length-N mother code into 32 subblocks of size N/32 and interlaces them.

The “puncturing” and “shortening” labels and arrows illustrate starting points and directions of puncturing and shortening operations, respectively.

Since puncturing is performed from the 1^{st} code bit, and shortening is performed from the last code bit, the rate matching module is efficiently implemented through a cyclic buffer. All mother code bits are placed in the cyclic buffer, and puncturing is done by selecting the bits in clockwise order, and shortening is done by selecting bits in counter-clockwise order. The cyclic buffer is illustrated in FIG. 6B.

FIG. 6B is a diagram illustrating puncturing and shortening with a cyclic buffer. At 602 in FIG. 6B, code bits of a codeword are illustrated in a vertical column, with punctured and shortened bits as shown. At 604, FIG. 6B illustrates a cyclic buffer, represented by a circle shape, and reading of code bits with no puncturing or shortening. The next two circles illustrate, respectively, cyclic buffers with dashed lines representing puncturing from the beginning of the buffer at 606 and shortening from the end of the buffer at 608.

Another polar code rate matching example involves an incremental freezing HARQ method, where transmissions of multiple short code words are supported. As more short codes are transmitted, the overall code length increases, and the overall code rate decreases.
1. In the first transmission, an (M₁, K) polar code is constructed, encoded and transmitted. The code rate is R₁=K/M₁. Usually, the code rate is determined such that R₁<C, where C₁ is the channel capacity of the first transmission. But in the case of faded channel or inaccurate channel estimation, there may be inequality R₁>C₁, and decoding will fail and a second transmission is required.
2. In the second transmission, K₂ least reliable information bits are selected from the K information bits in the first transmission. In practice, K₂ is chosen according to the estimated channel capacity of the second transmission. An (M₂, K₂) polar code is constructed accordingly and encoded and transmitted. However, if R₂>C₂, and decoding will fail again and a third transmission is required.
3. The third and fourth transmissions are constructed similarly, and so on.

At the receiver side, the decoder should always decode the last received code word, because it has the lowest code rate and thus the best chance of successful decoding. After the last transmission is correctly decoded, the corresponding information bits in all previous transmissions become known, and can be decoded as frozen bits with known values. This process is repeated as more code words are decoded, until all K bits in the first transmission is decoded. The term “incremental freezing” refers to the operations to additionally freeze some information bits in the previous transmissions once a later transmitted code word is decoded.

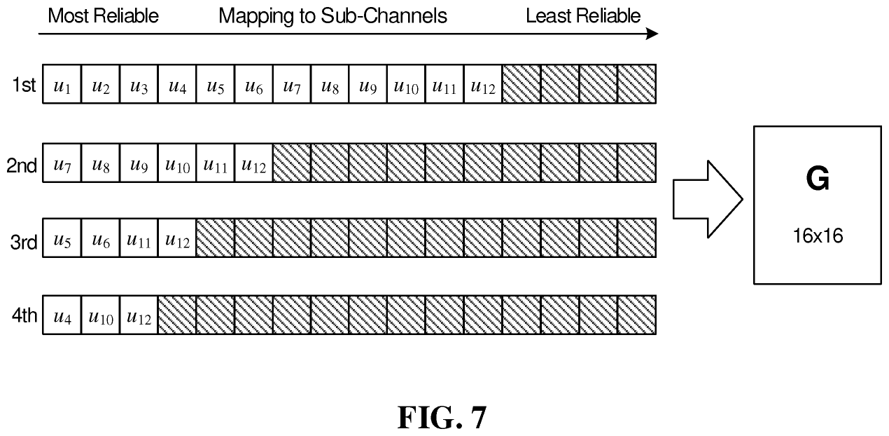

An example is illustrated in FIG. 7, where M₁=M₂=M₃=M₄=16, and K₁=12, K₂=6, K₃=4, K₄=3.

Parity-check (PC) polar codes may be used to improve minimum distance of polar codes. PC polar codes may also be used to support IR-HARQ. In the latter case, the PC bits are used to couple multiple retransmissions into a longer polar code with extra coding gain.

The PC functions used for IR-HARQ may be considered a special case, where some information bits are copied from the initial transmitted code block to a retransmitted code block. This one-to-one parity checking between the two shorter code blocks effectively couples the two code blocks into a longer code block.

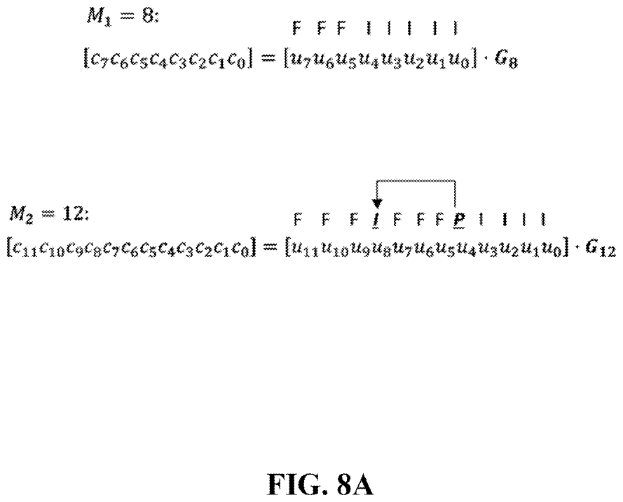

FIG. 8A is a diagram illustrating an example of polar encoding of an initial transmission and a retransmission. In this example, the initial transmission is a (M₁=8, K=5) polar code, where {u₀, u₁, u₂, u₃, u₄} is the information set, and {u₅, u₆, u₇} is the frozen set. Its encoding process is represented by the first (top) equation.

In the first retransmission, four additional code bits are transmitted. These four bits are coupled with the initially transmitted 8 bits to form a (M₂=12, K=5) polar code. The coupling is achieved by copying the value of u₄ to u₈ during encoding, thus generating a PC function u₄+u₈=0 (or equivalently u₈=u₄). As said, the largest index in this PC function corresponds to the PC bit (here u₈). During decoding, u₄ is decoded as an information bit, while u₈ is decoded as a PC bit using u₈=u₄. With {u₀, u₁, u₂, u₃, u₈} as the information set, {u₄} as the PC set, and {u₅, u₆, u₇, u₉, u₁₀, u₁₁} as the frozen set, the encoding process is represented by the second (bottom) equation.

In a second retransmission (not illustrated), the remaining four bits c₁₂, c₁₃, c₁₄, c₁₅ are transmitted to form a (M₃=16, K=5) polar code. But this time no new PC bits are generated.

From the polar transform matrix point of view, the three transmissions with effective code lengths M₁=8, M₂=12, M₃=16, are shown in FIG. 8B.

Rate-compatible LDPC coding is also another desirable technology for wireless applications. LDPC rate matching may involve a combination of puncturing, shortening, and repetition used together with quasi-cyclic lifting based on a base graph (BG) and a set of shifting values. In particular examples, the lifting size Ze is grouped into eight sets according to Z_{c}=aⱼ×2^{k}^{ⱼ}, where aⱼ∈{2, 3, 5, 7, 9, 11, 13, 15} and max(kⱼ)∈{7, 7, 6, 5, 5, 5, 4, 4}. The lifting sizes derived from the same aⱼ belong to the same set, and share the same shifting value. The shifting values for all the non-zero positions in the BG and for all groups of lifting sizes are stored in a single table. During the construction of a parity-check matrix, the lifting size Z_{c}, is determined first, then the set index j of the lifting size is obtained, and finally the shifting value is obtained from the table.

In general, a polar code construction scheme may need to specify the following parameters:

The information bit positions and the frozen bit positions.

Additionally or optionally, the parity-check bit positions or CRC bit positions.

Additionally or optionally, certain special types of parity-check (PC) bit positions or CRC bit positions.

The above bit positions under rate matching, for example, puncturing and shortening.

The above bit positions when IR-HARQ retransmission should be supported.

Some embodiments of the present disclosure include methods to select information bit positions, frozen bit positions, parity-check bit positions or CRC bit positions for rate matched polar codes. The methods also support IR-HARQ retransmission for polar codes. Some embodiments of the present disclosure may include the following objectives:

To obtain a stable performance under a wide range of code lengths and rates;

To support multiple transmissions and retransmissions, for example, with multiple redundancy versions.

Methods in accordance with embodiments of the present disclosure may include one or more of the following features:
Methods to select information/frozen/PC/CRC bit positions according to a nested reliability sequence;
   The sequence is divided into several subsequences, and their indices are separately read out for selecting information bit positions (and other bit positions);
   Set one or more parameters in order to determine which subsequence to be read out next for selecting information bit positions (and other bit positions);
   A hierarchical method to determine the information bit positions (and other bit positions) in each subblock of polar codes.
Methods to adjust code rates of certain subblocks in a polar code according to a nested reliability sequence;
   Adjusting (increasing or decreasing) the code rate of certain subblocks in a polar code by configuring the parameter(s) associated with specific subsequences;
   Methods to select information bit positions (and other bit positions) and adjust the code rate of certain subblocks at the same time.

Some embodiments of the present disclosure include one or more of the following features, which can be separately adopted, or work together as a complete solution.

Some embodiments of the present disclosure include methods to select information bit positions (and other bit positions) to support flexible code length and rates, and also to support potential IR-HARQ retransmissions. Some embodiments include two aspects or parts. The first part relates to selecting information bit positions considering rate matching. The second part relates to methods to adjust the code rate of certain blocks. An example general procedure includes the following steps:
1. Select a rate matching method (for example, puncturing, and shortening) based on coding parameters, such as the information block length K, rate matching output sequence length E, and/or (mother) code length N. And perform rate matching accordingly.
2. Based on the rate matching method, determine a threshold parameter (or a set of parameters) according to the above parameters. This threshold parameter can be obtained by certain rules, or looked up from a table.
3. Read out from a nested reliability sequence, and based on the threshold T, select information bit positions as part of the code construction.

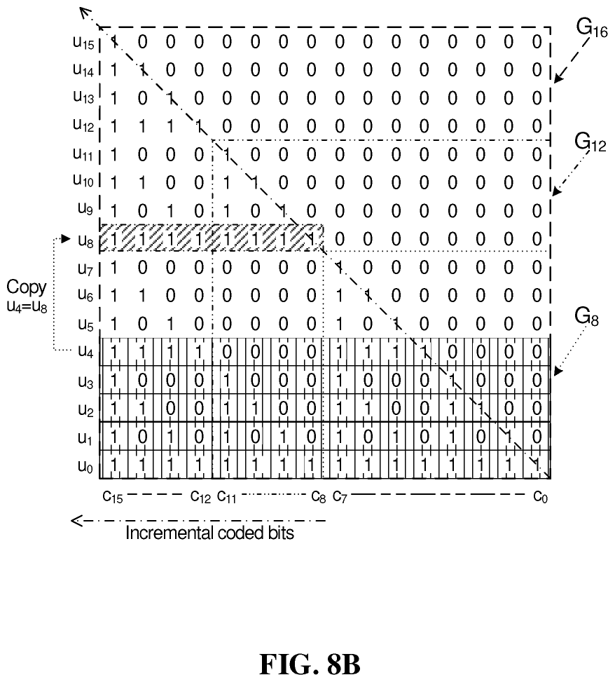

FIG. 9 illustrates such a general procedure. Information block length K and rate matching output sequence length E are shown at 902 as examples of coding parameters based upon which a rate matching method (puncture, shorten are shown by way of example) may be determined at 904. Features related to determining bit positions are shown at 910. T is an example of a threshold parameter determined based on the rate matching method, and also based on an additional coding parameter (shown as (mother) code length N in FIG. 9). A nested reliability sequence is shown at 920, and reading out from the nested reliability sequence based on the threshold Tis shown at 914. This reading out at 914 is to determine information bit positions as part of the code construction, as shown at 930.

Some embodiments of the present disclosure include methods to select information/frozen/PC/CRC bit positions according to a nested reliability sequence.
Divide the subchannels in the (mother) code into multiple subblocks;
The reliability sequence is divided into several subsequences, where each subsequence contains bit indices of a subblock of consecutive subchannel indices;
The reliability sequence is divided into several subsequences, where each subsequence contains bit indices of a subblock of non-consecutive subchannel indices;
Set one or more parameters in order to determine how to read out from the subsequences for selecting information bit positions (and other bit positions);
In the above methods, the value of thresholds depend on coding parameters and HARQ parameters or application scenarios.

A hierarchical or recursive method to determine the information bit positions (and other bit positions) in each subblock of polar codes.

Some embodiments of the present disclosure include methods to adjust code rates of certain subblocks in a polar code according to a nested reliability sequence;
If a subblock (defined in the first part) is heavily punctured or shortened, or will be potentially retransmitted, or belongs to a redundancy version for retransmission, the code rate of that subblock can be reduced, or the number of information bits in that block can be reduced. This will in turn increase the code rates of other subblocks.

The “change of subblock code rate” can be done once before the encoding of all redundancy versions (including initial transmission and future retransmissions), or before the encoding of each redundancy version (or each (re) transmission).

Adjusting (increasing or decreasing) the code rate of certain subblocks in a polar code by configuring the parameter(s) associated with specific subsequences;

Methods to select information bit positions (and other bit positions) and adjust the code rate of several subblocks at the same time.

In some embodiments of the present disclosure relating to methods to select information/frozen/PC/CRC bit positions according to a nested reliability sequence;
Divide the subchannels in the (mother) code into multiple subblocks;
   Each subblock can have consecutive subchannel indices
   Each subblock can have non-consecutive subchannel indices, but these subchannel indices may be consecutive before subblock interleaving.

In a first example, the reliability sequence is divided into several subsequences, where each subsequence contains bit indices of a subblock of consecutive subchannel indices as indicated in the first item above;

The length of the reliability sequence is power-of-2. Each subsequence is also power-of-2. The subsequence is obtained by extracting from the reliability sequence a power-of-2 number of consecutive bit indices.

Assuming the reliability sequence length is N, and the subsequence length is B. There will be S=N/B subblocks, indexed by s=[0, 1, 2, . . . , S−1]. The bit indices of the s-th subsequence is [s·B, s·B+1, s·B+2, . . . , s·B+B−1].

The subsequence is obtained by extracting the indices within the above-defined range, but maintaining the ordering of the indices in the reliability sequence.

Denote by

$${Q}_{0}^{N - 1}$$

the reliability sequence, the s-th subsequence

$${Q}_{0}^{B - 1}$$

is a subset of Polar sequence

$${Q}_{0}^{N - 1}$$

with all elements

$${Q}_{i}^{N}$$

of values larger than s·B−1 and less than s·B+B, ordered in ascending order of reliability

$$W ( {Q}_{0}^{B} ) < W ( {Q}_{1}^{B} ) < W ( {Q}_{2}^{B} ) < … < W ( {Q}_{B - 1}^{B} ) .$$

When S=2 and B=N/2, two subsequences, denoted by

$${Q}_{0}^{N / 2 - 1} and {Q}_{N / 2}^{N - 1} ,$$

can be extracted from a reliability sequence

$${Q}_{0}^{N - 1} .$$

The information bit positions are selected by reading out K₀ and K₁ bit indices by descending reliability order from both

$${Q}_{0}^{N / 2 - 1} and {Q}_{N / 2}^{N - 1} ,$$

respectively.

The subsequences are reliability sequences themselves, therefore can be further divided into more shorter subsequences. For example, the subsequence

$${Q}_{0}^{N / 2 - 1}$$

can be further divided into

$${Q}_{0}^{N / 4 - 1} and {Q}_{N / 4}^{N / 2 - 1}$$

according to the same rules; and the subsequence

$${Q}_{N / 2}^{N - 1}$$

can be further divided into

$${Q}_{N / 2}^{3 N / 4 - 1} and {Q}_{3 N / 4}^{N - 1}$$

according to the same rules too. The information bit positions are selected by reading out K₀, K₁, K₂ and K₃ bit indices by descending reliability order from both

$${Q}_{0}^{N / 4 - 1} , {Q}_{N / 4}^{N / 2 - 1} , {Q}_{N / 2}^{3 N / 4 - 1} and {Q}_{3 N / 4}^{N - 1} ,$$

respectively.

Alternatively, the same short subsequence may be used for all subblocks. Specifically, first obtain

$${Q}_{0}^{B - 1} ,$$

which a subset of Polar sequence

$${Q}_{0}^{N - 1}$$

with all elements

$${Q}_{i}^{N}$$

of values less than B, ordered in ascending order of reliability

$$W ( {Q}_{0}^{B} ) < W ( {Q}_{1}^{B} ) < W ( {Q}_{2}^{B} ) < … < W ( {Q}_{B - 1}^{B} ) ;$$

and then use

$${Q}_{0}^{B - 1} + s \cdot B$$

for all S subsequences for s=[0, 1, 2, . . . , S−1]. In the above example, first obtain

$${Q}_{0}^{N / 4 - 1} ,$$

and then define

$${Q}_{N / 4}^{N / 2 - 1} {=}^{Δ} {Q}_{0}^{N / 4 - 1} + N / 4 , and {Q}_{N / 2}^{3 N / 4 - 1} {=}^{Δ} {Q}_{0}^{N / 4 - 1} + N / 2 ,$$

$$and {Q}_{3 N / 4}^{N - 1} {=}^{Δ} {Q}_{0}^{N / 4 - 1} + 3 N / 4 .$$

This above described division can be recursively performed to create shorter sequences.

In a second example, the reliability sequence is divided into several subsequences, where each subsequence contains bit indices of a subblock of non-consecutive subchannel indices as in the second item above regarding dividing subchannels;
Same to above methods, except that a subsequence contains bit indices within a range of consecutive indices before interleaving of the original bit indices;
Assuming the reliability sequence length is N, and the subsequence length is B. There will be S=N/B subblocks, indexed by s=[0, 1, 2, . . . , S−1]. The bit indices of the s-th subsequence is [π(s·B), π(s·B+1), π(s·B+2), . . . , π(s·B+B−1)], where x is a permutation or interleaver function.

In the above methods, the interleaver π can be the rate matching interleaver, which is applied to a codeword before writing into the circular buffer for transmission.

The subsequence is obtained by extracting the indices within the above-defined range in the interleaved sequence, but maintaining the ordering of the indices in the reliability sequence.

Denote by

$${Q}_{0}^{N - 1}$$

the reliability sequence, the s-th subsequence

$${Q}_{0}^{B - 1}$$

is a subset of Polar sequence

$${Q}_{0}^{N - 1}$$

with all elements

$${Q}_{i}^{N}$$

of values within [π(s·B), π(s·B+1), π(s·B+2), . . . , π(s·B+B−1)], ordered in ascending order of reliability

$$W ( {Q}_{0}^{B} ) < W ( {Q}_{1}^{B} ) < W ( {Q}_{2}^{B} ) < … < W ( {Q}_{B - 1}^{B} ) .$$

When S=2 and B=N/2, extract two subsequences, denoted by

$${Q}_{0}^{N / 2 - 1} and {Q}_{N / 2}^{N - 1} ,$$

from reliability sequence

$${Q}_{0}^{N - 1} .$$

The subsequence

$${Q}_{0}^{N / 2 - 1}$$

contains bit indices within [π(0), π(1), π(2), . . . , π(N/2−1)]; and the subsequence

$${Q}_{N / 2}^{N - 1}$$

contains bit indices within [π(N/2), π(N/2+1), π(N/2+2), . . . , π(N−1)]. The information bit positions are selected by reading out K₀ and K₁ bit indices by descending reliability order from both

$${Q}_{0}^{N / 2 - 1} and {Q}_{N / 2}^{N - 1} ,$$

respectively.

Set one or more parameters in order to determine how to read out from subsequence for selecting information bit positions (and other bit positions);
A set of S−1 thresholds [T₁, T₂, . . . , T_{S-1}] can be configured to specify how to read out the information/frozen bit indices from the S subsequences.

The S subsequences can be further shortened by removing the pre-frozen bits. For example, if certain bit positions in the corresponding subblock are also shortened bit positions or punctured bit positions, they will be removed from the subsequence.

Given the S subsequences, a method includes reading out the bit indices from these S subsequences according to a descending reliability order, and thus obtaining the information bit indices in each subblock;

In the above method, reading out the bit indices in the long reliability sequence

$${Q}_{0}^{N - 1} ,$$

by descending reliability order, and comparing with the set of thresholds [T₁, T₂, . . . , T_{S-1}], can result in determining which subsequence to select from, in order to determine an information bit position in the corresponding subblock. Specifically, if the index read out from

$${Q}_{0}^{N - 1}$$

is

$${Q}_{i}^{N} ,$$

which satisfies

$${T}_{s} \leq {Q}_{i}^{N} < {T}_{s + 1} ,$$

then the next most reliable bit index from the s-th subsequence, and that bit index in the s-th subblock is marked as an information bit. This read-out process is carried out until altogether K information bit positions have been selected from all subblocks, where the K information bits can include CRC bits or a kind of minimum-weight parity-check (PC) bits.

Equivalently, given the S subsequences, a method includes reading out the bit indices from these S subsequences according to an ascending reliability order, and thus obtaining the frozen bit indices in each subblock;

In the above method, reading out the bit indices in the long reliability sequence

$${Q}_{0}^{N - 1} ,$$

by ascending reliability order, and comparing with the set of thresholds [T₁, T₂, . . . , T_{S-1}], can result in determining which subsequence to select from, in order to determine a frozen bit position in the corresponding subblock. Specifically, if the index read out from

$${Q}_{0}^{N - 1}$$

is

$${Q}_{i}^{N} ,$$

which satisfies

$${T}_{s} \leq {Q}_{i}^{N} < {T}_{s + 1} ,$$

then the next least reliable bit index from the s-th subsequence, and that bit index in the s-th subblock is marked as a frozen bit. This read-out process is carried out until altogether K information bit positions have been selected from all subblocks, where the K information bits can include CRC bits or a kind of minimum-weight parity-check (PC) bits.

When S=2, only one parameter T₁ is required according to the previous methods. The procedures become simpler, which is described as follows. From a reliability sequence

$${Q}_{0}^{N - 1} ,$$

two subsequences, denoted by

$${Q}_{0}^{N / 2 - 1} and {Q}_{N / 2}^{N - 1} ,$$

are extracted by the aforementioned methods. Then, bit indices from

$${Q}_{0}^{N - 1}$$

are sequentially read by descending reliability order. If the bit index to be read out is

$${Q}_{i}^{N} , and {Q}_{i}^{N} < {T}_{1} ,$$

then read the next bit index

$${Q}_{{i}_{0}}^{N / 2}$$

with the highest reliability from

$${Q}_{0}^{N / 2 - 1} ,$$

and mark the corresponding bit position (subchannel) as an information bit; otherwise if

$${Q}_{i}^{N} \geq {T}_{1} ,$$

then read the next bit index

$${Q}_{{i}_{1}}^{N / 2}$$

with the highest reliability from

$${Q}_{N / 2}^{N - 1} ,$$

and mark the corresponding bit position (subchannel) as an information bit. This process is continued until K₀ information bit positions are selected from

$${Q}_{0}^{N / 2 - 1} ,$$

and K₁ information bit positions are selected from

$${Q}_{N / 2}^{N - 1} ,$$

such that K₀+K₁=K reaches the total number of information bits (may include CRC bits or a kind of minimum-weight PC bits).

When S=2, the parameter T₁ should satisfy T₁<N/2 when there is rate matching (for example, puncturing or shortening), and T₁=N/2 when there is no rate matching (for example, E=N). For the cases with rate matching, the value of T₁ may monotonically decrease (or be non-increasing) as the value E/N decreases; or the value of T₁ may monotonically decrease (or be non-increasing) as the value K/N increases.

The following example constructs an N=16, K=8 polar code, by dividing into two subblocks with the threshold T=7. The reliability sequence is [0, 1, 2, 4, 8, 3, 5, 9, 6, 10, 12, 7, 11, 13, 14, 15].

In the conventional methods, the K=8 most reliable bit positions according to the sequence will be selected as information bit positions. Therefore, the information bit set is I=[6, 10, 12, 7, 11, 13, 14, 15].

In the example method, the reliability sequence [0, 1, 2, 4, 8, 3, 5, 9, 6, 10, 12, 7, 11, 13, 14, 15] is divided into two subsequences [0, 1, 2, 4, 3, 5, 6, 7] and [8, 9, 10, 12, 11, 13, 14, 15]. With the threshold T=7, 1 bit index is read out from [0, 1, 2, 4, 3, 5, 6, 7] and 7 bit indices are read out from [8, 9, 10, 12, 11, 13, 14, 15] by the time 8 information bit positions are selected. Therefore, the information bit indices are [7] from the first half of the code, and [9, 10, 12, 11, 13, 14, 15] from the second half of the code, which combines to generate the information bit set of I′=[7, 9, 10, 12, 11, 13, 14, 15]. Thus, the example method leads to a different polar code construction because I′≠I.

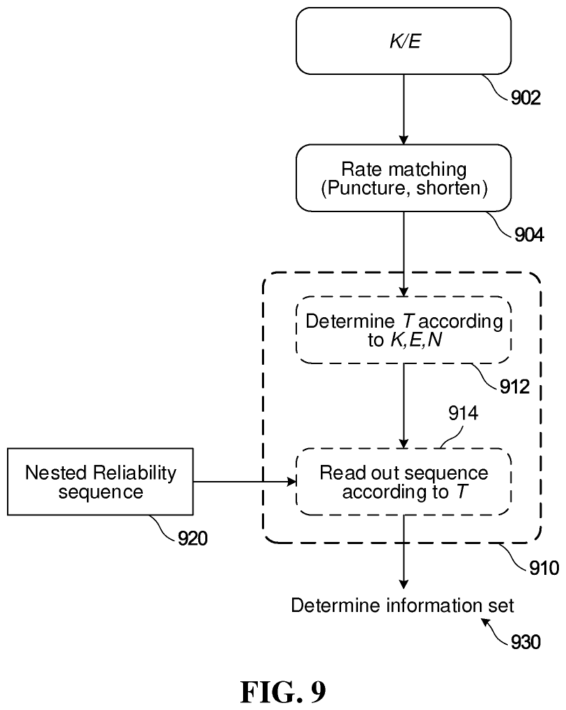

The process is illustrated in FIG. 10. The reliability sequence is shown at 1006, the two subsequences are shown at 1008 and 1010, 1020 represents a comparison operation or comparator, and frozen and information bit indices in each subblock of the code are shown at 1002 and 1004. Bit indices are also shown at 1030.

Consistent with the example above, the reliability sequence 1006 is divided into the two subsequences 1008 and 1010, and each bit index of the information set is selected from one of the ordered subsequences based on an order of the bit indices in the ordered sequence 1006 and, in the example shown, the threshold T=7. One at a time, bit indices are read, in order of decreasing reliability, from the ordered sequence 1006 and, based on the comparison at 1020 with the threshold T=7, an information bit position is selected from one of the two subsequences 1008 and 1010.

As an example, the first bit index read from the ordered sequence 1006 is bit index 15, which is greater than the threshold T=7, so the next most reliable bit index (also bit index 15) is read from the subsequence 1010, and bit index 15 is the first information bit index. Similarly, bit indices 14, 13, and 11 are read from the ordered sequence 1006 and compared to the threshold T=7, resulting in selection of bit indices 14, 13, and 11 from the subsequence 1010. The next bit index in the ordered sequence 1006 is bit index 7, which is equal to the threshold T=7, so in the example shown the next bit index in the subsequence 1010 (bit index 12) is selected as an information bit index. This is where the information bit set in the example becomes different from the information bit set that would be selected based on the ordered sequence 1006.

The bit indices 12 and 10, which are next in order in the ordered sequence 1006, result in selection of bit indices 10 and 9 from the subsequence 1010. Then bit index 6 is next in the ordered sequence 1006, and is below the threshold T=7, so the next bit index 7 in the subsequence 1008 is selected as the next information bit index. The distribution of information bit indices and frozen bit indices in the two subblocks of the code are shown at 1002 and 1004.

The information bit set that would be selected from the ordered reliability sequence 1006 according to conventional code construction techniques is I=[6, 10, 12, 7, 11, 13, 14, 15], in which two bit indices are in the first subblock (half) of the code 1002 in the example shown. In the information bit set of I′=[7, 9, 10, 12, 11, 13, 14, 15], based on selecting information bit indices from the subsequences 1008 and 1010 as described, only one bit index is in the first subblock (half) of the code 1002.

With fewer information bits in the first subblock 1002, the code rate of this subblock is reduced. It has been found through simulation that reducing code rate in the first half of a polar code may improve performance (BLER, for example), but at a certain point performance may begin to degrade because the code rate of the first half becomes too low and, for the same K, code rate of the second half becomes too high. In the example shown in FIG. 10, information bit index selection and thus code rate for each subblock is controlled in part by the threshold T.

The example in FIG. 10 is illustrative of embodiments in which information/frozen/PC/CRC bit positions are selected according to a nested reliability sequence, and parameter (threshold T) is set in order to determine how to read out from subsequences for selecting information bit positions (and other bit positions). The following further discussion of FIG. 10 explains one of the examples above in additional detail.

In FIG. 10, the bit indices at 1030 are intended to illustrate one option for dividing the bit indices of a polar code (also referred to herein as subchannels in the (mother) code) into multiple subblocks 1002 and 1004. Each subblock includes consecutive indices in the example shown.

The reliability sequence 1006 is divided into the subsequences 1008 and 1010, and each subsequence contains bit indices of a subblock 1002 or 1004 of consecutive indices. The length of the reliability sequence 1006 is power-of-2, and the length of each subsequence 1008 and 1010 is also power-of-2. Each subsequence 1008 and 1010 is obtained by extracting, from the reliability sequence 1006, a power-of-2 number of consecutive bit indices consistent with a corresponding subblock 1002 or 1004.

Using notation from an example above, the reliability sequence length is N=16, the subsequence length is B=8, and there will be S=N/B=2 subblocks 1002, 1004, which may be indexed by s=[0, . . . , S−1]=[0, 1]. The bit indices of the s-th subsequence, and also the s-th subblock, are [s·B, s·B+1, s·B+2, . . . , s·B+B−1]. In the example shown, the subblocks include bit indices [0, 1, 2, . . . , 7] at 1002 and the bit indices [8, 9, 10, . . . , 15] at 1004.

Each subsequence is obtained by extracting these bit indices, within the range of consecutive bit indices for each subblock and subsequence, but maintaining the ordering of the indices in the reliability sequence 1006. Referring to the subblocks of consecutive bit indices [0, 1, 2, . . . , 7] and [8, 9, 10, . . . , 15], according to the ordering of the bit indices of each of these subblocks in the reliability sequence 1006, the subsequence 1008 is ordered [0, 1, 2, 4, 3, 5, 6, 7], and the subsequence 1008 is ordered [8, 9, 10, 12, 11, 13, 14, 15].

Denote by

$${Q}_{0}^{N - 1}$$

the reliability sequence, the s-th subsequence

$${Q}_{0}^{B - 1}$$

is a subset of Polar sequence

$${Q}_{0}^{N - 1}$$

with all elements

$${Q}_{i}^{N}$$

of values larger than s·B−1 and less than s·B+B, ordered in ascending order of reliability

$$W ( {Q}_{0}^{B} ) < W ( {Q}_{1}^{B} ) < W ( {Q}_{2}^{B} ) < … < W ( {Q}_{B - 1}^{B} ) .$$

In this notation, the example in FIG. 10 illustrates

$${Q}_{0}^{15}$$

as the reliability sequence 1006, two subsequences

$${Q}_{0}^{B - 1}$$

(which could also be denoted

$${Q}_{s \cdot B}^{s \cdot B - 1} ,$$

for

$${Q}_{0}^{B - 1}$$

at 1008 and

$${Q}_{0}^{2 B - 1}$$

at 1010), each with B entries and being a subset of Polar sequence

$${Q}_{0}^{15}$$

with all elements

$${Q}_{i}^{N}$$

of values larger than s·B−1 and less than s·B+B, ordered in ascending order of reliability.

When S=2 and B=N/2 as in the example shown in FIG. 10, two subsequences

$${Q}_{0}^{N / 2 - 1}$$

at 1008 and

$${Q}_{N / 2}^{N - 1}$$

at 1010 can be extracted from the reliability sequence

$${Q}_{0}^{N - 1}$$

at 1006. The information bit positions are selected by reading out K₀=1 and K₁=7 bit indices in the example shown, by descending reliability order from both

$${Q}_{0}^{N / 2 - 1} and {Q}_{N / 2}^{N - 1} ,$$

respectively.

This is one example of dividing bit indices, obtaining subsequences, and selecting information bit indices. Other embodiments may include similar or different features.

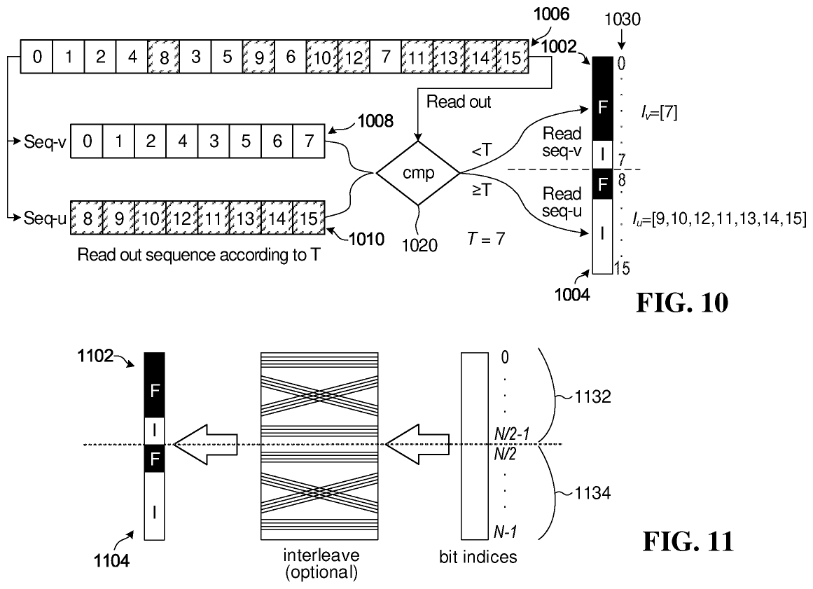

For example, a reliability sequence may be divided into subsequences that each contain bit indices of a subblock of non-consecutive indices. FIG. 11 illustrates an example of a code constructed using interleaved bit indices. Constructing the code may be substantially the same as in FIG. 10, except that a subsequence contains bit indices within a range of consecutive indices before interleaving of the original bit indices. The original bit indices for a length N code are shown at the right in FIG. 11, two subblocks 1132 and 1134 are shown as an example. An interleave operation is shown in FIG. 11 as optional, to illustrate that such interleaving may be applied in some embodiments but not necessarily in all embodiments. Interleaving may be subblock interleaving, for example, to change the order of bit indices within one or more subblocks 1132, 1134. Before interleaving, the bit indices at the right in FIG. 11 are consecutive.

Referring to notation that is used in an example above, assuming the reliability sequence length is N and the subsequence length is B, there will be S=N/B subblocks (2 in the example shown), which may be indexed by s=[0, 1, 2, . . . , S−1] (s=[0,1] for the example in FIG. 11, the same as in FIG. 10). The bit indices of the s-th subsequence are [π(s·B), π(s·B+1), π(s·B+2), . . . , π(s·B+B−1)], where a is a permutation or interleaver function. As described at least above, the interleaver π can be the rate matching interleaver for example.

Each subsequence may be obtained by extracting the indices within the range in an interleaved sequence, but maintaining the ordering of the indices in the reliability sequence. For subsequence interleaving, bit indices are interleaved within a subblock, and code construction may be the same as in FIG. 10, as shown in FIG. 11 at 1102, 1104. However, if the interleaving is not restricted to each subblock, then subsequences and code construction will be different in FIG. 11.

In the above methods, the value of thresholds depend on coding parameters and thresholds may depend on HARQ parameters or application scenarios.

The threshold values [T₁, T₂, . . . , T_{S-1}] determine the value of information bit numbers [K₀, K₁, . . . , K_{S-1}] in each block, therefore determining the code construction.

The configuration of [T₁, T₂, . . . , T_{S-1}] values depend on one or more of the following parameters: mother code length N, information block length K, rate matching output sequence length E, code rate R, rate matching method (for example, puncture or shorten), redundancy version index rυ_{id}, decoder type (for example, SC or SCL with a specific list size) and application scenarios (for example, immersive communications, URLLC or HRLLC, mMTC).

The threshold(s) may be obtained by certain rules, for example:

```
if E/N<θ₀
  T=T₀;
else if E/N<θ₁
  T=T₁;
...
else if E/N<θₗ₋₁
  T=Tₗ₋₁;
else
  T=Tₗ;
end if
where θ₀< θ₁<...< θₗ₋₁, and T₀≤ T₁≤...≤ Tₗ₋₁≤ Tₗ.
```

In the above example, HRLLC refers to Hyper Reliable & Low-Latency Communication, which was recently defined by the International Telecommunication Union (ITU) as a more advanced version of 5G URLLC.

The threshold(s) may be obtained from a look-up table, or two tables depending on the rate matching scheme (one table for puncturing and one table for shortening).

| Threshold T | E/N<θ₀ | θ₀≤E/N<θ₁ | ... | θₗ₋₂≤E/N<θₗ₋₁ | θₗ₋₁≤E/N |
|---|---|---|---|---|---|
| K/N<η₀ | T_{0,0} | T_{0,1} | ... | T_{0,l-1} | T_{0,l} |
| η₀≤K/N<η₁ | T_{1,0} | T_{1,1} | ... | T_{1,l-1} | T_{1,l} |
| ... | ... | ... | ... | ... | ... |
| ηₗ₋₂≤K/N<ηₗ₋₁ | T_{l-1,0} | T_{l-1,1} | ... | T_{l-1,l-1} | T_{l-1,l} |
| ηₗ₋₁≤K/N | T_{l,0} | T_{l,1} | ... | T_{l,l-1} | T_{l,l} |

In the above table, T_{0,s}≤T_{1,s}≤ . . . ≤T_{l-1,a}≤T_{l,s} for all s∈{0, 1, . . . , l}, and T_{s,0}≤T_{s,1}≤ . . . ≤T_{s,l-1}≤T_{s,l} all s∈{0, 1, . . . , l};

A useful range for T has been found, based on simulation, to be from 7/16 to ½ times N for any mother code length, and 15/32 times N may be particularly preferred as a lower limit for T.

In practice, it may be desirable to specify thresholds with integers rather than fractions. Therefore, a fractional number threshold may be multiplied by the mother code length to determine a threshold. A power-of-2 mother code length that is larger than a power-of-2 denominator of a fractional number threshold will always yield an integer value threshold, and accordingly in some embodiments a fractional number threshold is determined so that mother code length is larger than the denominator, and both the mother code length and the denominator are both power-of-2 numbers.

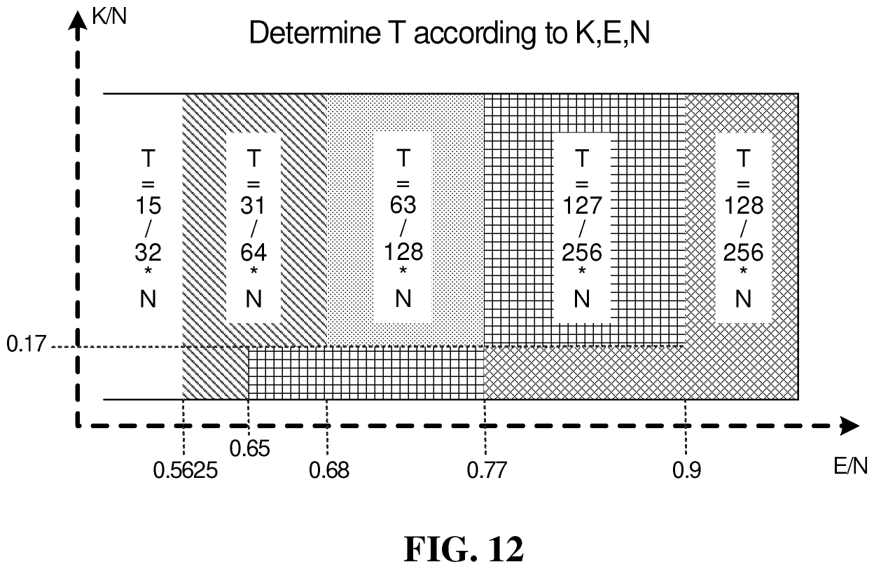

FIG. 12 provides a graphical illustration of threshold determination according to an embodiment. In the example shown, the threshold range is from 15/32 to 128/256 (which is ½) times mother code length N, and is based on K, E, and N. The transition values shown on each axis in FIG. 12 were determined based on simulation, and are examples only. The particular examples for T are also non-limiting examples. In general, FIG. 12 illustrates that T may be based at least in part on E (and N in the example shown), in that T decreases with decreasing E/N and increases with increasing E/N, such that lower values of T are preferred where rate matching or otherwise reducing the number of mother code bits that are to be output (for transmission for example) is more aggressive relative to mother code length.

A threshold T may also or instead be determined based on code rate K/N. In FIG. 12, for example, higher threshold values are preferred for certain lower code rates, in particular for K/N below 0.17 and E/N in the range [0.65, 0.77] or for K/N below 0.17 and E/N in the range [0.77, 0.9].

A hierarchical or recursive method to determine the information bit positions (and other bit positions) in each subblock of polar codes may be provided.

Segment a long mother code to a pre-defined number (for example, S₁=2 or 4) of subblocks each time, and do this recursively to generate Sₜ subblocks within a previously generated subblock each time. This will result in S₁·S₂ subblocks (and S₁·S₂ subsequences) after the second iteration, and S₁·S₂·S₃ subblocks (and S₁·S₂·S₃ subsequences) after the third iteration, and so on.

To save description and implementation complexity, fix the number of subblocks to be divided each time (for example, S₁=S₂= . . . =Sₜ=S=2 or 4) of subblocks each time, and do this recursively to generate S² subblocks (and Se subsequences) after the second iteration, and S³ subblocks (and S³ subsequences) after the third iteration, and so on.

For the recursive code construction, first allocate [K₀, K₁, . . . , K_{S-1}] information bits to each subblock of size N/S according to the thresholds [T₁, T₂, . . . , T_{S-1}], based on the aforementioned methods. Then, for each subblock of size N/S, further divide to S subblocks. Take the s-th subblock for example, allocate [K_{s,0}, K_{s,1}, . . . , K_{s,S-1}] information bits to each subblock of size N/S² according to the thresholds [T_{s,0}, T_{s,1}, . . . , T_{s,S-1}], and do this for all S∈[0, 1, . . . , S−1].

To simplify implementation, the number of recursive iterations can be set to 2 or 3.

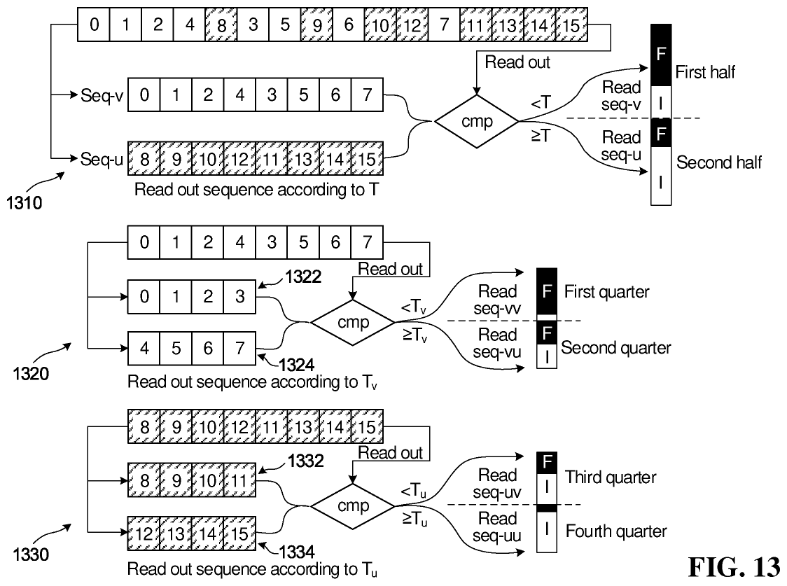

FIG. 13 illustrates an example of such a hierarchical or recursive method of constructing a polar code. At 1310, FIG. 13 illustrates a first iteration, in which a long mother code of length 16 is segmented into S₁=2 subblocks, labelled “First half” and “Second half”. This segmenting is repeated recursively to generate Sₜ=2 subblocks within each previously generated subblock each time. This results in 4 subblocks (and 4 subsequences) of length 4, as shown at 1320 and 1330. The First half subblock at 1310 is segmented into the First quarter and the Second quarter at 1320, and the Second half subblock at 1310 is segmented into the Third quarter and the Fourth quarter at 1330, after the second iteration. Further iterations may follow, in a similar manner.

For bit index selection, the threshold T and a bit index read from the ordered sequence at 1310 determine whether to read out from the subsequence seq-v (also shown at 1320) or the subsequence seq-u (also shown at 1330). The threshold Tᵥ and a bit index read from the subsequence seq-v determine, when the bit index read from the ordered sequence at 1310 is greater than or equal to T, whether to read out from the subsequence 1322 or the subsequence 1324. The threshold Tᵤ and a bit index read from the subsequence seq-u determine, when the bit index read from the ordered sequence at 1310 is less than T, whether to read out from the subsequence 1332 or the subsequence 1334.

Although frozen and information bit indices are indicated by blank and shaded portions of the First half and the Second half at 1310 for completeness, it should be noted that bit index selection is based on the bit indices and thresholds at 1320 and 1330 in this example.

In practice, further iterations or a higher number of subsequences may provide better performance up to a point, but then provide diminishing returns. For example, one division or segmentation and two subsequences may be preferred, and possibly one further iteration to provide three thresholds (for four subsequences) may also be used. Further subdivision or segmentation to eight or more segments and subsequences is expected to be overly complex for the potential additional performance gain.

Some embodiments of the present disclosure relate to methods to adjust code rates of certain subblocks in a polar code according to a nested reliability sequence.

If a subblock (defined in the first part) is heavily punctured or shortened, or will be potentially retransmitted, or belongs to a redundancy version for retransmission, reduce the code rate of that subblock, or the number of information bits in that block. This will in turn increase the code rates of other subblocks.

This is achieved not by introducing a new subroutine, but also embedded in the same subroutine for selecting information bits as introduced in the first part.

In this way, the information bits are selected all at once, thus saving complexity.

The “change of subblock code rate” can be done once before the encoding of all redundancy versions (including initial transmission and future retransmissions), or before the encoding of each redundancy version (or each (re) transmission).

If the subblock-wise rate adjustment is done once before the encoding of all redundancy versions, adjust the code rate for all subblocks at once before the encoding, and encode the entire codeword. The code bits are written into a circular buffer for transmission. In each redundancy version (or each (re) transmission), the corresponding code bits in the circular buffer are read out according to pre-defined starting positions and ending positions for that redundancy version.

If the subblock-wise rate adjustment is done every time before the encoding of each redundancy version, adjust the code rate for the subblocks in the current redundancy version (or the current transmission), and encode the part of codeword that has overlap with the current redundancy version (or the current transmission). The code bits are written into a circular buffer for transmission for this redundancy version (or this (re) transmission) only. The corresponding code bits in the circular buffer are read out according to pre-defined starting positions and ending positions for this redundancy version.

Some embodiments may involve adjusting (increasing or decreasing) the code rate of certain subblocks in a polar code by configuring the parameter(s) associated with specific subsequences.

For a subblock, use additional threshold(s) to select information bits.

A subblock is within a larger subblock. One threshold can be used for the larger subblock, and an additional threshold can be used for the embedded subblock. This can be used to impose a higher or lower code rate within the smaller subblock.

If the code rate of a particular subblock is to be reduced, an additional threshold that applies only to this subblock may be set to be a lower value than the threshold for the larger subblock. That is, to select a bit index from that particular subblock as an information bit position, the bit index read out from the longer reliability sequence has to be smaller than the additional threshold as well if it falls in the smaller subblock.

When S=2, one parameter T was used for selecting information bit positions for the first half and second half of the code word. From a reliability sequence

$${Q}_{0}^{N - 1} ,$$

two subsequences, denoted by

$${Q}_{0}^{N / 2 - 1} and {Q}_{N / 2}^{N - 1} ,$$

are extracted by the aforementioned methods. On top of that, a smaller subblock is defined in

$${Q}_{3 N / 8}^{N / 2 - 1} ,$$

which contains the bit indices in [3·N/8, 3·N/8+1, 3·N/8+2, . . . , N/2−1]. For this subblock, an additional threshold T° is defined, which can be smaller than T, for selecting information bit positions within

$${Q}_{3 N / 8}^{N / 2 - 1} .$$

Similarly, bit indices are sequentially read from

$${Q}_{0}^{N - 1}$$

by descending reliability order. If the bit index to be read out is

$${Q}_{i}^{N} ,$$

and the following two conditions (i)

$${Q}_{i}^{N} < T$$

and (ii)

$${Q}_{i}^{N} < {T}^{′}$$

when

$${Q}_{i}^{N} ∈ {Q}_{3 N / 8}^{N / 2 - 1}$$

are satisfied at the same time, the next bit index

$${Q}_{{i}_{0}}^{N / 2}$$

with the highest reliability is read from

$${Q}_{0}^{N / 2 - 1} ,$$

and the corresponding bit position (subchannel) is marked as an information bit; otherwise if

$${Q}_{i}^{N} \geq T or {Q}_{i}^{N} \geq {T}^{′}$$

when

$${Q}_{i}^{N} ∈ {Q}_{3 N / 8}^{N / 2 - 1} ,$$

the nest bit index

$${Q}_{{i}_{1}}^{N / 2}$$

with the highest reliability is read from

$${Q}_{N / 2}^{N - 1} ,$$

and the corresponding bit position (subchannel) is marked as an information bit. This process is continued until K₀ information bit positions are selected from

$${Q}_{0}^{N / 2 - 1} ,$$

and K₁ information pit positions are selected from

$${Q}_{N / 2}^{N - 1} ,$$

such that K₀+K₁=K reaches the total number of information bits (may include CRC bits or a kind of minimum-weight PC bits).

When S=2, the parameter T should satisfy T<N/2 when there is rate matching (e.g., puncturing or shortening), and T=N/2 when there is no rate matching (e.g., E=N). For the cases with rate matching, the value of T may monotonically decrease (or non-increasing) as the value E/N decreases; or the value of T may monotonically decrease (or non-increasing) as the value K/N increases. On top of that, the additional threshold T° for a subblock in the first half of the code may be smaller than parameter T, that is, T°<T.

The following example constructs an N=16, K=8 polar code, by dividing into two subblocks with the threshold T=7, and T°=5 for the subblock [6,7]. The reliability sequence is [0, 1, 2, 4, 8, 3, 5, 9, 6, 10, 12, 7, 11, 13, 14, 15].

In the conventional methods, the K=8 most reliable bit positions according to the sequence will be selected as information bit positions. Therefore, the information bit set is I=[6, 10, 12, 7, 11, 13, 14, 15].

In a previous example method, with the threshold T=7, 1 bit index is read out from [0, 1, 2, 4, 3, 5, 6, 7] and 7 bit indices are read out from [8, 9, 10, 12, 11, 13, 14, 15], and the information bit set is I′=[7, 9, 10, 12, 11, 13, 14, 15].

In another example method, the reliability sequence [0, 1, 2, 4, 8, 3, 5, 9, 6, 10, 12, 7, 11, 13, 14, 15] is divided into two subsequences [0, 1, 2, 4, 3, 5, 6, 7] and [8, 9, 10, 12, 11, 13, 14, 15]. With the threshold T=7, 1 bit index is read out from [0, 1, 2, 4, 3, 5, 6, 7], which is [7]. However, because [7] belongs to the smaller subblock [6,7] and the additional threshold T°=5 should be now applied, the bit index [7] cannot be selected for information bit position and the next most-reliable bit index from the second half, which is [8] should be selected instead as the information bit position. Therefore, no information bit indices are selected from the first half of the code, and [8, 9, 10, 12, 11, 13, 14, 15] from the second half of the code, which combines to generate the information bit set of I″=[8, 9, 10, 12, 11, 13, 14, 15]. Thus, the example method leads to a different polar code construction because I″≠I′≠I.

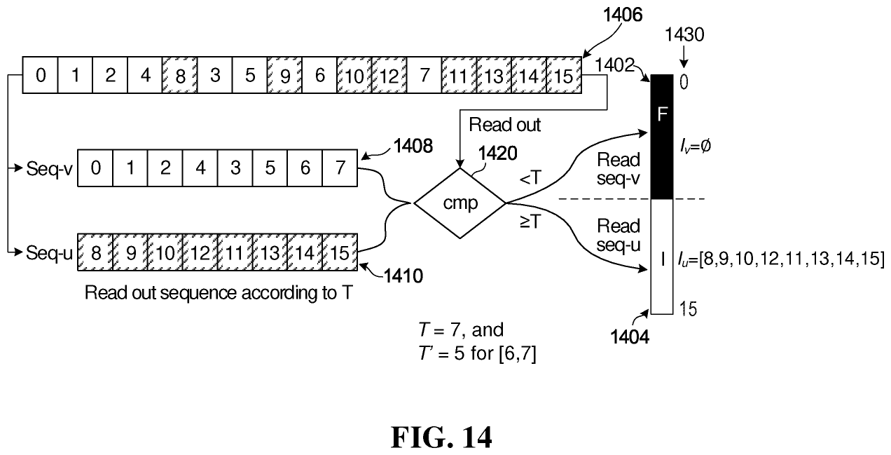

The process is illustrated in FIG. 14. Similar to FIG. 10, FIG. 14 illustrates an example of constructing an N=16, K=8 polar code by dividing into two subblocks, but in FIG. 14 there are multiple thresholds, including one threshold T=7 for the two subblocks and another threshold T°=5 for the embedded subblock [6,7]. The reliability sequence is shown at 1406, the two subsequences are shown at 1408 and 1410, 1420 represents a comparison operation or comparator, and frozen and information bit indices in each subblock of the code are shown at 1402 and 1404. Bit indices are also shown at 1430.

Consistent with the example above, the reliability sequence 1406 is divided into the two subsequences 1408 and 1410. With the threshold T=7, when the bit index 6 is read out from the ordered sequence 1406, this is the first time that a bit index is below T and therefore the first time that a bit index is to be read out from the subsequence 1408 for selection as an information bit index. The bit index 7 would be read out from the subsequence 1408, but belongs to the smaller subblock [6,7] and the additional threshold T°=5 is now applied. The bit index 7 is greater than T°=5, and therefore bit index 7 cannot be selected from the smaller subblock as an information bit index, and the next most-reliable bit index from the second half, which is [8] in this example, is instead selected as an information bit position.

Selection of other bit indices in FIG. 14 may be as described above with reference to FIG. 10.

Methods to select information bit positions (and other bit positions) and adjust the code rate of several subblocks at the same time are also possible.

When a bit index is read out from the reliability sequence, the bit index can be compared with multiple threshold parameters, and some of the comparisons can be done on condition that the bit index is in certain subblocks.

The conditions can be:

$${Q}_{i}^{N} < T and \{ {Q}_{i}^{N} < {T}_{1} and {Q}_{i}^{N} ∈ {Q}_{1} \} and \{ {Q}_{i}^{N} < {T}_{2} and {Q}_{i}^{N} ∈ {Q}_{2} \} ,$$

and so on.

The procedure to select information bits based on multiple thresholds can be described by the following pseudocodes:

Denote by

$${\overline{Q}}_{I}^{N}$$

the information set to pe determined for a polar code with mother code length N.

```
i₁ = N/2 − 1;
i₂ = N/2 − 1;
for i = 0 to K − 1
    $if {Q}_{i}^{N} < T and \{ {Q}_{i}^{N} < {T}_{1} and {Q}_{i}^{N} ∈ {Q}_{1} \} and \{ {Q}_{i}^{N} < {T}_{2} and {Q}_{i}^{N} ∈ {Q}_{2} \}$
      ${\overline{Q}}_{I}^{N} = {\overline{Q}}_{I}^{N} ⋃ {\overline{Q}}_{{i}_{1}}^{N / 2}$
      i₁ = i₁ − 1
    else
      ${\overline{Q}}_{I}^{N2} = {\overline{Q}}_{I}^{2 N} ⋃ {\overline{Q}}_{{i}_{2}}^{N / 2}$
      i₂ = i₂ − 1
    end if
end for
```

An example of rate matching of a particular code is shown in the following pseudo codes:

In the following, K is the information block length, and E is the rate matching output length,

$${n}_{P C}^{w m} , and {Q}_{0}^{2 N - 1}$$

is the reliability ordered sequence for a mother code with length 2N, and

$${\overline{Q}}_{F , pre}^{2 N}$$

is the pre-frozen bit positions in the mother code due to rate matching and/or for performance enhancement.

### Determination of Threshold

Denote by T the bit selection threshold to be used in the following steps.

```
if E/N < 9/16
  T = 15/32 · N
else if E/N < 11/16
  T = 31/64 · N
else if E/N < 3/4
  T = 63/128 · N
else if E/N < 7/8
  T = 127/256 · N
else
  T = N/2
end if
```

### Information Bit Set Selection

The information bit indices

$${\overline{Q}}_{{I}_{u}}^{N}$$

in the initial transmission are selected as follows.

$${\overline{P}}_{0 , t m p}^{D - 1} = {P}_{0}^{N - 1} ∖ {\overline{Q}}_{F , pre}^{N} ,$$

and its elements are

$${\overline{P}}_{i , tmp}^{D - 1} , and D = \vert {\overline{P}}_{0 , t m p}^{D - 1} \vert .$$

$${\overline{P}}_{0 , tmp 1}^{{D}_{1} - 1}$$

is a subset of Polar sequence

$${\overline{P}}_{0 , tmp}^{{D}_{1} - 1}$$

with all elements

$${\overline{P}}_{i , tmp}^{D}$$

of values larger than N−1 and less than 3N/2, ordered in ascending order of reliability

$$W ( {\overline{P}}_{0 , tmp 1}^{{D}_{1}} ) < W ( {\overline{P}}_{1 , tmp 1}^{{D}_{1}} ) < W ( {\overline{P}}_{2 , tmp 1}^{{D}_{1}} ) < … < W ( {\overline{P}}_{{D}_{1} - 1 , tmp 1}^{{D}_{1}} ) , and$$

$${D}_{1} = \vert - {\overline{P}}_{0 , tmp 1}^{{D}_{1} - 1} \vert . {\overline{P}}_{0 , tmp 2}^{{D}_{2} - 1}$$

is a subset of Polar sequence

$${\overline{P}}_{0 , tmp}^{D - 1}$$

with all elements

$${\overline{P}}_{i , tmp}^{D}$$

of values larger than 3N/2−1 and less than 2N, ordered in ascending order of reliability

$$W ( {\overline{P}}_{0 , tmp 2}^{{D}_{2}} ) < W ( {\overline{P}}_{1 , tmp 2}^{{D}_{2}} ) < W ( {\overline{P}}_{2 , tmp 2}^{{D}_{2}} ) < … < W ( {\overline{P}}_{{D}_{2} - 1 , tmp 2}^{{D}_{2}} ) , and$$

$${D}_{2} = \vert {\overline{P}}_{0 , tmp 2}^{{D}_{2} - 1} \vert .$$

```
${\overline{Q}}_{{I}_{u}}^{N} = ∅$
i₁ = D₁ − 1
i₂ = D₂ − 1
for i = D − 1 to D − K
  $if {\overline{P}}_{i , tempt}^{D} < T + N$
    ${\overline{Q}}_{{I}_{u}}^{N} = {\overline{Q}}_{{I}_{u}}^{N} ⋃ {\overline{P}}_{{i}_{1 , tmp 1}}^{{D}_{1}}$
    i₁ = i₁ − 1
  else
    ${\overline{Q}}_{{I}_{u}}^{N} = {\overline{Q}}_{{I}_{u}}^{N} ⋃ {\overline{P}}_{{i}_{2 , tmp 2}}^{{D}_{2}}$
    i₂ = i₂ − 1
  end if
end for
```

The information bit indices

$${\overline{Q}}_{I}^{2 N}$$

combining the mural transmission and the retransmissions are selected as follows.

$${\overline{Q}}_{0 , tmp}^{D - 1} = {Q}_{0}^{2 N - 1} ∖ {\overline{Q}}_{F , pre}^{2 N} ,$$

and its elements

$${\overline{Q}}_{i , tmp}^{D} , and D = \vert {\overline{Q}}_{0 , tmp}^{D - 1} \vert .$$

$${\overline{Q}}_{0 , tmp 1}^{{D}_{1} - 1}$$

is a subset of Polar sequence

$${\overline{Q}}_{0 , tmp}^{D - 1}$$

with all elements

$${\overline{Q}}_{i , tmp}^{D}$$

of values less than N, ordered in ascending order of reliability

$$W ( {\overline{Q}}_{0 , tmp 1}^{{D}_{1}} ) < W ( {\overline{Q}}_{1 , tmp 1}^{{D}_{1}} ) < W ( {\overline{Q}}_{2 , tmp 1}^{{D}_{1}} ) < … < W ( {\overline{Q}}_{{D}_{1} - 1 , tmp 1}^{{D}_{1}} ) , and$$

$${D}_{1} = \vert {P}_{0 , tmp 1}^{- {D}_{1} - 1} \vert . {\overline{Q}}_{0 , tmp 2}^{{D}_{2} - 1}$$

is a subset of Polar sequence

$${\overline{Q}}_{0 , tmp}^{D - 1}$$

with all elements

$${\overline{Q}}_{i , tmp}^{D}$$

of values larger than N−1 and less than 2N, ordered in ascending order of reliability

$$W ( {\overline{Q}}_{0 , tmp 2}^{{D}_{2}} ) < W ( {\overline{Q}}_{1 , tmp 2}^{{D}_{2}} ) < W ( {\overline{Q}}_{2 , tmp 2}^{{D}_{2}} ) < … < W ( {\overline{Q}}_{{D}_{2} - 1 , tmp 2}^{{D}_{2}} ) , and$$

$${D}_{2} = \vert {\overline{Q}}_{0 , tmp 2}^{{D}_{2} - 1} \vert .$$

```
  ${\overline{Q}}_{I}^{2 N} = ∅$
  i₁ = D₁ − 1
  i₂ = D₂ − 1
  T₁ = 63/64 · N
  T₂ = N
  for i = D − 1 to D − K
    $if {\overline{Q}}_{i , tmp}^{D} < {T}_{2} and ( {\overline{Q}}_{i , tmp}^{D} < {T}_{1} or {\overline{Q}}_{i , tmp}^{D} ∉ [ π ( 3 / 4 \cdot N ) , π ( 3 / 4 \cdot N + 1 ) , π ( 3 / 4 \cdot N + 2 ) , … , π ( N - 1 ) ] ) ,$
where π is a rate matching interleaving sequence.
      ${\overline{Q}}_{I}^{2 N} = {\overline{Q}}_{I}^{2 N} ⋃ {\overline{Q}}_{{i}_{1} , tmp 1}^{{D}_{1}} ;$
      i₁ = i₁ − 1;
    else
      ${\overline{Q}}_{I}^{2 N} = {\overline{Q}}_{I}^{2 N} ⋃ {\overline{Q}}_{{i}_{2} , tmp 2}^{{D}_{2}} ;$
      i₂ = i₂ − 1;
    end if
end for
```

The above descriptions mainly determine the following rate matching parameters:
Threshold parameter;
Number of subblocks;
The specific subblocks for rate adjustment.

These parameters can either be pre-defined in standard specifications, or signaled using Radio Resource Control (RRC) messages or UCI control information.

Standard specifications represent one example of how parameters may be pre-defined. RRC and UCI are examples of signaling that may indicate parameters.

### Overview

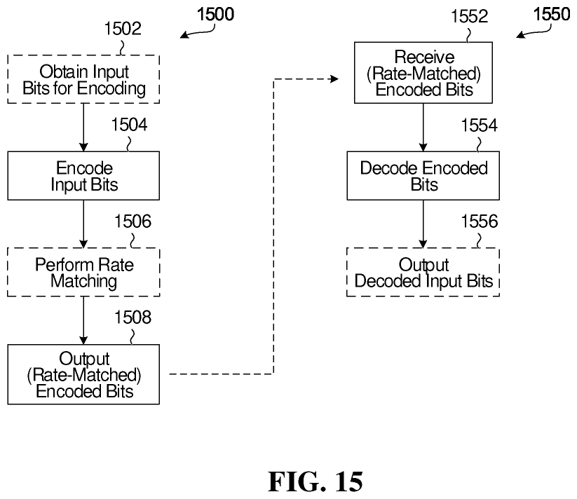

Various aspects of the present disclosure are described above and shown in the drawings by way of example. FIG. 15 illustrates more general example methods according to embodiments. At the left, 1500 in FIG. 15 illustrates operations or features that may be provided or supported at an encoder or transmitter-side device, and at the right, 1550 illustrates operations or features that may be provided or supported at a decoder or receiver-side device. For ease of reference, a device at which encoding and/or transmitting features may be implemented or supported may be called a first communication device, and a device at which decoding and/or receiving features may be implemented or supported may be called a second communication device. Embodiments may involve either or both of such devices.

With reference first to 1500, encoding input bits by a polar code to obtain a number of encoded bits is shown at 1504. Encoded bits may be referred to as code bits or coded bits, for example, and may be described as being obtained or generated by encoding input bits by a polar code. Encoding at 1504 may be implemented or performed by an encoder or a processor, for example. A polar code includes bit indices for placing bit values before encoding, and the bit indices include a first set of bit indices for values of the input bits and a second set of bit indices for a predetermined bit value. The first set of bit indices may also be referred to as an information set (for values of information bits and possibly other bits such as parity bits and/or CRC bits), and the second set of bit indices may also be referred to as a frozen set (for a predetermined frozen bit value such as 0). The information and frozen sets in FIGS. 10, 11, 13, and 14 are examples of the above-referenced first and second sets of bit indices.

Each bit index of the first set, or each bit index of the second set, is selected from an ordered subsequence. As described herein, bit indices may be selected for an information set or a frozen set, by reading bit indices in increasing or decreasing order of rank such as reliability. More generally, each bit index of the first set or the second set is selected from an ordered subsequence, and other (non-selected) bit indices of a polar code comprise the second set or the first set, respectively.

Bit indices, which are also referred to herein as bit positions, may be selected in any of various ways, and in examples herein selection involves reading bit indices from one or more subsequences. For example, an ordered sequence such as a nested reliability sequence may be divided into several subsequences, and bit indices may be separately read out from one or more of the subsequences for selecting bit indices for a set, which may be an information set or a frozen set for example. Selected bit indices are selected for one set, and bit indices that are not selected are part of another set. It should be appreciated that bit indices may be selected without necessarily performing a read operation.

Overall, bit indices may be selected from one subsequence or from more than one subsequence. In FIGS. 10 and 13, for example, each set of bit indices (information and frozen in the examples shown) includes bit indices from more than one subsequence, whereas in the example shown in FIG. 14, each set of bit indices includes bit indices from only one subsequence (1410 for the information set and 1408 for the frozen set). The examples in FIGS. 10 and 13 therefore illustrate embodiments in which bit index selection switches between different subsequences as bit indices are selected for a set, and the example in FIG. 14 illustrates an embodiment in which there is no such switching. In both cases, however, there are multiple subsequences from which bit indices may be selected, and bit indices in a set may be selected one or more than one of those subsequences.

Considering any individual bit index that is selected, each bit index selected from an ordered subsequence. That ordered subsequence is a one of multiple ordered subsequences of bit indices that together include all of the bit indices of the polar code by which the input bits are encoded at 1504. According to one example herein, the same subsequence is used for all subblocks, and in this case as well the subsequences include all of the bit indices of the polar code. The same subsequence option is described by way of example above as using

$${Q}_{0}^{B - 1} + s \cdot B$$

for all S subsequences (for s=[0, 1, 2, . . . , S−1]), and in this example the “+s·B” term means that bit indices in the same subsequence are adjusted for each subblock, such that overall the S subsequences together include all of the bit indices of the polar code, from 0 to (B−1)+(S−1)·B=N−1.

Each selected bit index is selected, from an ordered subsequence, based on an order of the polar code bit indices in a longer ordered sequence that also includes the bit indices of the polar code. The ordered subsequences together include all of the bit indices of the polar code, and the longer ordered sequence also includes all of those bit indices. The longer ordered sequence controls or determines which subsequence is used for each bit index selection, but bit indices are selected from the subsequences. With reference to FIG. 10, the ordered sequence at 1006 includes all of the bit indices of the example N=16 polar code, and the two subsequences at 1008, 1010, together, also include all of those bit indices. As described in detail at least above, selecting each bit index for either of the sets (information set or frozen set in this example) from a subsequence is based on the order of the bit indices in the ordered sequence at 1006.

A method may also involve outputting encoded bits, as shown by way of example at 1508 in FIG. 15. Encoded bits may be output through or via any of various types of interface, including a communication interface in the case of transmitting the encoded bits. Embodiments are not in any way restricted to any particular type of interface. The encoded bits may be transmitted at 1508 by a first communication device to a second communication device in a wireless communication network, for example. Transmission of encoded bits is illustrated by the dashed line from 1508 to 1552, but not all embodiments necessarily involve transmitting encoded bits. For example, in some embodiments encoded bits generated by the encoding at 1504 may be output by an encoder at 1506 for further processing or handling, and may or may not be transmitted. The coded bits may be output to memory, for example.

In some embodiments, the ordered subsequences are based on subblocks of the bit indices of the polar code, but in an order according to the ordered sequence. With reference to FIG. 10 as an example, each ordered subsequence 1008, 1010 includes bit indices of a respective one of different subsets of the bit indices ([0, 1, . . . , 7] and [8, 9, . . . , 15] in the example shown) that together include all of the bit indices, and the bit indices in each ordered subsequence are in an order according to the ordered sequence 1006. This is explained in further detail at least above. The subsets referenced in this example may also be referred to as subblocks.

Subblock-based embodiments may be described as dividing subchannels in a (mother) code into multiple subblocks, dividing an ordered sequence such as a reliability sequence into several subsequences with each subsequence including bit indices of a subblock of consecutive or non-consecutive subchannel indices, setting one or more parameters (such as one or more thresholds) in order to determine how to read out or otherwise select bit indices from the subsequences for selecting information bit positions (and/or other bit positions). Dividing may also be referred to as segmenting. Subchannels in a code correspond to bit indices or bit positions. Setting parameters may also be referred to as obtaining (or otherwise determining) parameters.

Thus, some embodiments may involve obtaining, by determining or generating for example, the ordered subsequences based on different subsets of the bit indices of the polar code and ordering the bit indices in each ordered subsequence in an order according to the ordered sequence. These features may be part of the encoding at 1504, or implemented separately from the encoding. An ordered sequence and subsequences may be pre-generated and stored, for example. A method may involve obtaining the ordered sequence and the subsequences, and such obtaining may involve generating or determining the ordered sequence and the subsequences, or accessing a stored or otherwise available ordered sequence and subsequences.

Each of the different subsets may include a subset of consecutive bit indices in a natural or sequential order of the bit indices. This is consistent with the example shown in FIG. 10, and such subsets may be referred to as subblocks of consecutive or sequential indices.

In the case of subblocks of consecutive bit indices, the ordered sequence is divided into several subsequences, where each subsequence contains bit indices of a subblock of consecutive subchannel indices. The length of a reliability sequence, for example, may be a power-of-2, and each subsequence may also be of a length that is a power-of-2. Each subsequence may be obtained in this example by extracting, from the reliability sequence, a power-of-2 number of consecutive bit indices, but maintaining the ordering of the indices in the reliability sequence.

A detailed example of such an embodiment that involves subblocks of consecutive bit indices is provided above, with reference to a reliability sequence of length N, subsequence length B, S=N/B subblocks indexed by s=[0, 1, 2, . . . , S−1], and bit indices of each s-th subsequence [s·B, s·B+1, s·B+2, . . . , s·B+B−1].

One of the subsets, or each of several or all of the subsets, may include non-consecutive bit indices. Embodiments may involve subsets of consecutive bit indices, subsets of non-consecutive bit indices, or potentially a mix of subsets including one or more subsets of consecutive bit indices and one or more subsets of non-consecutive bit indices. More generally, different subsets of the bit indices of a polar code may include a subset or multiple subsets of non-consecutive bit indices, or each of the different subsets may be a subset of non-consecutive bit indices.

In FIG. 11, for example, optional interleaving may be applied, and the bit indices in a (or each) subset of non-consecutive bit indices are in an interleaved order. In the example shown, the bit indices within each of the two subblocks 1132, 1134 may be interleaved (also referred to herein as subblock interleaving), in which case each subblock includes non-consecutive bit indices. In other embodiments, not all subblocks are interleaved, or interleaving might not necessarily change the order of bit indices in every subblock, and this is one example of a mixed subblock embodiments in which one or more subblocks each include consecutive bit indices and one or more other subblocks each include non-consecutive bit indices.

In the case of one or more subblocks of non-consecutive bit indices, the ordered sequence is divided into several subsequences, but each subsequence contains bit indices of a subblock of non-consecutive subchannel indices. Bit index selection in the case of subblocks of non-consecutive bit indices may be substantially the same as for subblocks of consecutive bit indices. In some embodiments, one or more subsequences may contain bit indices within a range of consecutive indices before interleaving of original bit indices in a subblock.

A detailed example of an embodiment that involves subblocks of non-consecutive bit indices is provided above, with reference to a reliability sequence of length N, subsequence length B, S=N/B subblocks indexed by s=[0, 1, 2, . . . , S−1], and bit indices of each s-th subsequence [π(s·B), π(s·B+1), π(s·B+2), . . . , π(s·B+B−1)].

Subblocks may be obtained in any of various ways. For example, bit indices may be segmented into subblocks in one segmenting iteration or operation. Other embodiments may involve recursive segmentation in multiple iterations. Different subsets may be recursively segmented from among the bit indices of a polar code. Thus, a method may involve obtaining subblocks by segmenting the bit indices of a polar code into different subsets, and the segmenting may involve recursively segmenting the bit indices in some embodiments.

This type of segmenting may also be referred to as hierarchical. In general, a method may involve segmenting a (mother) code, or bit indices thereof, into a number (for example, S₁=2 or 4) of subblocks each time, recursively, to generate Sₜ subblocks within a previously generated subblock each time. In an example above, this results in S₁·S₂ subblocks (and S₁·S₂ subsequences) after the second iteration, and S₁·S₂·S₃ subblocks (and S₁·S₂·S₃ subsequences) after the third iteration, and so on. The number of subblocks into which a code or each subblock from a preceding iteration is to be divided each time may be fixed, as in another example described in further detail above.

Consistent with this detailed example, recursive code construction may involve allocating [K₀, K₁, . . . , K_{S-1}] information bits to each subblock of size N/S according to the thresholds [T₁, T₂, . . . , T_{S-1}], based on other examples herein, and then further segmenting each subblock of size N/S into S subblocks. Considering an s-th subblock for example, this may involve allocating [K_{s,0}, K_{s,1}, . . . , K_{s,S-1}] information bits to each subblock of size N/S² according to the thresholds [T_{s,0}, T_{s,1}, . . . , T_{s,S-1}], and doing this for all s∈[0, 1, . . . , S−1].

FIG. 13 also illustrates an example of such a hierarchical or recursive method of constructing a polar code, and a method may include one or more features consistent with FIG. 13. For example, for bit index selection, a method may involve comparing a threshold such as T and a bit index read from the ordered sequence at 1310 to determine the subsequence (the subsequence seq-v (also shown at 1320) or the subsequence seq-u (also shown at 1330)) from which another bit index is to be read. A method may then involve comparing another threshold (Tᵥ or Tᵤ in the example shown) and that other bit index read from the subsequence seq-v or seq-u to determine a further subsequence (one of 1322 or 1324; or one of 1332 or 1334) from which a bit index is to be selected for a set of bit indices (information set or frozen set in the example shown).

A decision as to the particular subsequence from which each bit index of a set is to be selected may be made based on not only a bit index from the ordered sequence, but also one or more thresholds. In the context of the above-referenced first set and second set of bit indices, the ordered subsequence from which each bit index of the first set or the second set is selected may be further based on one or more bit index thresholds. FIG. 10 illustrates an example with one bit index threshold, and FIGS. 13 and 14 illustrate different examples of multiple-threshold embodiments.

A method may involve determining the ordered subsequence from which each bit index of the first set or the second set is to be selected, based on one or more comparisons involving the one or more bit index thresholds and a respective bit index that is read, in order, from the ordered sequence, and selecting each bit index from the determined ordered subsequence from which each bit index is to be selected. These features are consistent with the examples shown in FIGS. 10, 13, and 14.

In some embodiments, a comparison may be directly between one or more thresholds and the bit index that is read from the ordered sequence, or in other words determining the ordered subsequence from which each bit index of the first set or the second set is to be selected is based on comparing the one or more bit index thresholds with the bit index that is read from the ordered sequence. An example of such a comparison of a bit index i with threshold is as follows:

```
if (i<threshold)
  ...
else
  ...
end if
```

A comparison need not necessarily be direct, and may involve one or more functions of the threshold(s) and the bit index. An example of such a comparison is as follows, where i denotes a bit index and f( ) and g( ) are two functions:

```
if (f(i)<g(threshold))
  ...
else
  ...
end if
```

Thus, in the case of direct comparisons the determination as to the subsequence from which each bit index is to be selected may be made by comparing a bit index, from the ordered sequence, with one or more thresholds. For example, the decision or determination may be made by comparing a bit index with a threshold (as in FIG. 10 for example), or with multiple thresholds (as in FIG. 14 for example) depending on a range into which the bit index falls. In the case of one threshold, there is one binary comparison result, which determines which of two subsequences to read a bit index from for a bit index set. In the latter case, there are multiple comparison results, which may be further logically combined (through OR, and/or AND for example) to determine the subsequence from which a bit index is to be selected.

FIG. 13 illustrates another multiple threshold example, with multiple comparison results from comparing respective thresholds with respective bit indices from the ordered sequences at 1310 and one of the ordered subsequences at the top at 1320 or 1330.

The comparisons in FIGS. 10, 13, and 14 are examples, and embodiments are not limited to these or any other specific comparisons. For example, logical operators might not only be used to combine comparison results as described above, but may also or instead be applied as a comparison condition, such as “if (NOT (i>threshold))”. This type of condition may also be expressed as an “else” condition, for example “if (i>threshold) . . . else . . . ”.

A function or condition may involve one or more set operations such as “belong to ∈” or “is a subset” or other set operations. Examples of comparison conditions that involve set operations or operators includes “if (i∈(index set))” or “if (i∉S)”. These are examples of bit index functions, and in FIG. 14 the threshold T° is applied if a bit index is within the set [6, 7].

In some embodiments, a function involves one or more arithmetic operations. For example, a condition may be “if (i−N/2)<threshold”, to apply a threshold to the second half of a code. Equivalently, the condition may be “if i<(threshold+N/2)” to apply the threshold to the second half of the code. Similarly, to apply a threshold to the first half of a code, a condition may be “if i<threshold/2” or “if (i+N/2)<threshold” to apply the method to the first half of the code. Such functions may be useful, for example, when a threshold is specified for the whole codeword.

Interleaving is another example of a function that may be involved in determining the ordered subsequence from which a bit index is to be selected.

These examples are not mutually exclusive, and more generally multiple functions or conditions may be applied in combination. For example, a determination of the ordered subsequence from which a bit index is to be selected may involve one or more thresholds, one or more comparisons, one or more functions, and logical combinations. The following are examples:
“if (NOT (i>T₁)) AND (i∉S)”
or
“if (i<T₁) AND ((i<T₂) OR (i∉S))”
or
“if (i<T₁) AND ((i<T₂) OR (i∉π(S))),
where T₁ and T₂ are different thresholds, S is a set of bit indices, π(x) is an interleaving function such as a rate matching interleaving function. In some embodiments, S can be a consecutive bit index sequence, such as S=[¾·N, ¾·N+1, ¾·N+2, . . . , N−1].

Each ordered subsequence may indicate the bit indices in the ordered subsequence in an order of rank (increasing or decreasing) for placing the bit values for encoding by the polar code. Reliability is one example of a rank according to which bit indices may be ordered in ordered subsequences or an ordered sequence.

Selecting each bit index in the first set or the second set may then involve selecting, from an ordered subsequence: a next bit index, that has not previously been selected, in decreasing order of rank from the determined ordered subsequence as a bit index of the first set; or a next bit index, that has not previously been selected, in increasing order of rank from the determined ordered subsequence as a bit index of the second set. Bit index selection in increasing order of rank is related to selecting bit indices for the predetermined bit value (the frozen set, for example), and bit index selection in decreasing order of rank is related to selecting bit indices for values of input bits.

In these examples, an action is performed following the decision or determination as to which ordered subsequence should be read from to obtain (select) a bit index for the first set or the second set. That action is selecting a bit index. If the set for which bit indices are being selected is an information set (an example of the above-referenced first set), then the action is selecting the most reliable unread (not previously selected) bit index in the subsequence to be read out and included in the information set; if the set is a frozen set (an example of the above-referenced second set), then the action is selecting the least reliable unread (not previously selected) bit index in the subsequence to be read out and included in the frozen set.

Other examples that involve thresholds are also provided herein, and one detailed example above involves configuring a set of S−1 thresholds [T₁, T₂, . . . , T_{S-1}] to specify or control how to read out (or more generally select) information/frozen bit indices from S subsequences. Reading out or otherwise selecting the bit indices from one or more of the S subsequences according to a descending reliability order, for example, may obtain the information bit indices in each subblock, or reading out or otherwise selecting the bit indices from one or more of the S subsequences according to an ascending reliability order, for example, may obtain the frozen bit indices in each subblock. Descriptions of comparisons that involve one or more thresholds are also provided in this example above.

Comparison and bit index selection features may be part of the encoding at 1504, for example, or implemented separately from the encoding. The first and second sets of bit indices may be pre-generated and stored, for example. A method may involve obtaining the first and second sets of bit indices, and such obtaining may involve generating or determining the first and second sets of bit indices, or accessing stored or otherwise available first and second sets of bit indices.

Each threshold may be based on any of various parameters or characteristics, such as a code length of the polar code, an information block length of the first set of bit indices, and a length of a rate matching output sequence. A rate matching output sequence may include a reduced number of encoded bits, in the case of rate matching that involves puncturing or shortening for example, and an increased number of encoded bits, in the case of rate matching that involves repetition for example.

A method may involve selecting a rate matching method (for example, puncturing and/or shortening as shown at 904 in FIG. 9 for example, or repetition in some embodiments) based on coding parameters, such as information block length K, rate matching output sequence length E, and/or (mother) code length N. Rate matching may then be performed accordingly. A method that involves rate matching may also involve determining, based on the rate matching method, a threshold parameter (or a set of parameters), which can be obtained by certain rules, or looked up from a table for example. As described in further detail elsewhere herein, selecting bit indices may involve reading out bit indices from an ordered sequence such as a nested reliability sequence, and based on the threshold(s), selecting bit indices as part of the code construction.

In FIG. 15, performing rate matching is shown as an optional feature at 1506. Rate matching may be performed in some embodiments, but need not be performed in all embodiments. Also regarding rate matching, encoded bits from the encoding at 1504 may be output at 1508, and rate matching may be subsequently performed, prior to transmitting encoded bits for example. In embodiments that involve rate matching, a method may include transmitting a rate matching output sequence from a first communication device to a second communication device in a wireless communication network, for example. A rate matching output sequence may also be referred to as rate-matched encoded bits, as shown at 1508 in FIG. 15.

Code length, information block length, and rate matching output sequence length are examples of parameters that may be used in combination in some embodiments in obtaining one or more thresholds. The one or more thresholds may be or include a threshold that is further based on any one or more of the following, for example: a code rate; a type of rate matching for obtaining the rate matching output sequence; a redundancy version; a decoder type for decoding the encoded bits; an application scenario. For example, in the context of per-subblock code rate control, there may be multiple thresholds, but not all of those thresholds are necessarily based on a code rate. In FIG. 14, for example, T° is based on a reduced code rate, but T need not necessarily also be based on a code rate.

More generally, multiple thresholds may include a threshold that is based on a target code rate associated with one of the ordered subsequences, as shown by way of example in FIG. 14 for a reduced target code rate associated with the ordered subsequence 1408. The reduced code rate is a code rate related to the v-code (subblock 1402) in the example shown, but the code rate of the v-code is associated with the ordered subsequence 1408 in the sense that any information bit indices in the v-code would be bit indices in the ordered subsequence 1408.

Thus, in some embodiments, code rates of certain subblocks in a polar code may be adjusted according to an ordered sequence, such as a nested reliability sequence. If a subblock is heavily punctured or shortened, or will be potentially retransmitted, or belongs to a redundancy version for retransmission, for example, then the code rate of that subblock can be reduced, or the number of information bits in that block can be reduced. This will in turn increase the code rates of other subblocks. As shown by way of example in FIG. 14, the code rate associated with one subsequence and subblock is adjusted by configuring a parameter (threshold in the example shown) associated with a specific subsequence. More generally, adjusting (increasing or decreasing) the code rate of certain subblocks in a polar code may involve configuring one or more parameters (such as one or more thresholds) associated with one or more specific subsequences. Code rate adjustment, by configuring one or more parameters such as thresholds for example, may be performed once before encoding of all redundancy versions (including and initial transmission and future retransmission(s)), or before encoding of each redundancy version (or each (re) transmission).

Code rate adjustment can thus be achieved without introducing a new subroutine or procedure, but rather by embedding code rate adjustment in the same subroutine or procedure for selecting bit indices. Bit indices can then be selected all at once, saving complexity over other approaches to code rate adjustment.

As an example, if subblock-wise code rate adjustment is done once before the encoding of all redundancy versions, a method may involve adjusting the code rate for all subblocks at once before the encoding, and encoding an entire codeword. Encoded bits may be written into a circular buffer for transmission, and in each redundancy version (or each (re) transmission), the corresponding encoded bits in the circular buffer may be read out according to pre-defined starting positions and ending positions for that redundancy version. If subblock-wise code rate adjustment is done before encoding of each redundancy version, a method may involve adjusting the code rate for the subblocks in a current redundancy version (or a current transmission), and encoding part of a codeword that has overlap with the current redundancy version (or the current transmission). The encoded bits may be written into a circular buffer for transmission for this redundancy version (or this (re) transmission) only. The corresponding encoded bits in the circular buffer may then be read out according to pre-defined starting positions and ending positions for the current redundancy version.

According to an example above, adjusting (increasing or decreasing) the code rate of certain subblocks in a polar code involves configuring the parameter(s) associated with specific subsequences. For a subblock, one or more additional thresholds may be used to select information bits. A subblock that is within a larger subblock may be referred to as an embedded subblock. One threshold can be used for the larger subblock, and an additional threshold can be used for the embedded subblock, to impose a higher or lower code rate within the smaller subblock. This is described in detail at least above, in the context of an example that involves two subsequences

$${Q}_{0}^{N / 2 - 1} and {Q}_{N / 2}^{N - 1}$$

and a smaller subsequence

$${Q}_{3 N / 8}^{N / 2 - 1}$$

for a smaller subblock.

With reference to FIG. 14, a method may involve segmenting an ordered sequence (shown by way of example as the reliability sequence 1406) is divided into multiple subsequences, shown by way of example as the subsequences 1408 and 1410. Based on comparing a bit index (6) from the ordered sequence 1406 with the threshold T=7, when the bit index 6 is read out from the ordered sequence 1406, it is determined that a bit index is to be selected from the subsequence 1408. Based on comparing another bit index (7) in the subsequence 1408 with a second threshold T°=5 because the bit index 7 belongs to the smaller subblock [6,7], it is determined that a bit index is to be selected from the subsequence 1410.

Pseudocode examples are also provided above for selecting bit indices and adjusting code rate at the same time, and for other features disclosed herein.

With reference again to FIG. 15, obtaining input bits for encoding, as shown at 1502, may be performed or supported separately from the encoding at 1504 and/or the outputting at 1508. The obtaining at 1502 may involve any of various operations, such as any one or more of the following: collecting or otherwise receiving input bits from one or more devices and/or services; accessing input bits in a memory; encoding or otherwise pre-processing input bits before the encoding at 1504.

Other operations or features may also be supported or provided in some embodiments. For example, a method may involve modifying one or more of the subsequences to remove certain bit indices, such as bit indices in a corresponding subblock that are (or are to be) shortened or punctured. Removing such bit indices is also referred to herein as removing pre-frozen bits.

Another example of features that may be provided in some embodiments but are not explicitly shown in FIG. 15 relates to signaling. Some embodiments may involve transmitting and/or receiving signaling or any of various types of indications related to encoding and/or transmission for example. More generally, embodiments may involve communicating, in a wireless communication network, signaling indicative of any of various parameters. Parameters related to one or more of subblocks, ordered sequences, ordered subsequences, thresholds, sets of bit indices, encoding, rate matching, transmission, reception, or decoding may be indicated in signaling.

Such communicating of signaling may involve transmitting the signaling by an encoder/encoding device or a transmitter/transmitting device that is to transmit encoded bits, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which coded bits are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving signaling from the network device, and/or a decoder/decoding device or a receiver/receiving device receiving signaling from the network device.

Other features may also or instead be supported. Several examples herein involve selecting bit indices based on an ordered sequence and one or more of multiple ordered sequences. Bit index selection may be part of encoding at 1504, or performed in advance. For example, information and frozen sets may be pre-generated and then accessed in memory or otherwise obtained for the encoding at 1504. Thus, more generally, a method may involve obtaining bit indices for placing bit values, for encoding by a polar code to obtain a number of encoded bits. As in other embodiments, the bit indices include a first set of bit indices for values of input bits and a second set of bit indices for a predetermined bit value, and each bit index of the first set or the second set is selected, from an ordered subsequence, based on an order of the bit indices in an ordered sequence. Such a method may also include encoding the input bits by the polar code as shown at 1504 to obtain the encoded bits; and outputting the encoded bits as shown at 1508.

Bit value placement for encoding by a polar code is normally in accordance with a reliability sequence. In some embodiments, a base reliability sequence may be modified to generate a modified sequence in which bit indices are in a different order, and bit values may then be placed on bit indices according to the different order, without segmenting an ordered sequence and using that sequence and subsequence for bit index selection at encoding time.

The ordered sequence that includes all bit indices may indicate the bit indices in a base order of rank for placing the bit values for encoding by the polar code. A nested reliability sequence is an example of such a sequence, in which the rank is reliability and the order of rank is reliability order. Obtaining the bit indices for placement of bit values (information bit indices and frozen bit indices) may involve modifying the ordered sequence to obtain a modified ordered sequence that indicates the bit indices in a modified order consistent with each bit index of the first set or the second set being selected as described herein, and then obtaining the first set of bit indices and the second set of bit indices from the modified ordered sequence.

This feature may become more apparent from reference to FIG. 10 as an example. Here, the ordered sequence 1006 includes all of the bit indices, and indicates those bit indices in a base order of rank (reliability) for placing bit values for encoding. According to conventional polar coding based on that ordered sequence, the information set includes the most reliable bit indices according to the order of bit indices in the ordered sequence, and the frozen set includes the least reliable bit indices. For K=8 as in FIG. 10, the information set would include the 8 most reliable bit indices in the ordered sequence 1006, which are (in decreasing reliability order) 15, 14, 13, 11, 7, 12, 10, 6 in the example shown. This ordered sequence 1006 may be modified to indicate the bit indices in a different order, which already captures or embodies the order in which bit indices would be selected from the subsequences. As shown in FIG. 10, the full information set when subsequence-based bit index selection is used as disclosed herein would include bit indices 15, 14, 13, 11, 12, 10, 9, 7, which is different from the information set based on the ordered sequence 1006 alone.

A modified ordered sequence that indicates the bit indices in an order according to subsequence-based selection as disclosed herein could be used in much the same way as the ordered sequence 1006. With such a modified ordered sequence, bit indices for bit value placement may be selected from the modified ordered sequence. The order of bit indices in such a modified ordered sequence captures or embodies the order in which the bit indices would be selected for a set based on the ordered sequence 1006 and one or both of the subsequences 1008, 1010, but can be pre-generated and used directly for bit value placement at encoding time.

Thus, in some embodiments a modified ordered sequence indicates bit indices in an order according to bit index selection based on an ordered sequence and one or more subsequences, and that modified ordered sequence is used in encoding according to a polar code. In the example above, the highest-rank bit indices in the modified ordered sequence would be as follows, in increasing order of rank: 7, 9, 10, 12, 11, 13, 14, 15.

This type of modified ordered sequence approach may be used in other disclosed embodiments, and not only the embodiment in FIG. 10. Offline, pre-generation of a modified ordered sequence may be especially preferred in multiple-threshold embodiments, including but not limited to those shown by way of example in FIGS. 13 and 14, which are more complex and may therefore require more time for bit index selection.

Offline pre-generation may also or instead be used in other embodiments to generate, and store in memory for example, modified ordered sequences or information/frozen sets. Multiple modified ordered sequences or information/frozen sets may be generated for different coding scenarios, and a modified ordered sequence or information/frozen sets may then be selected based on one or more coding parameters.

At 1550, FIG. 15 illustrates various decoding and/or receiving counterparts of features shown at 1500. From a receiving device perspective, the receiving at 1552 is intended to represent receiving a number of encoded bits that were encoded by obtaining bit indices. The bit indices are for placing bit values for encoding by a polar code, and include a first set of bit indices for values of input bits and a second set of bit indices for a predetermined bit value. Each bit index of the first set or the second set has been selected, from an ordered subsequence, which is one of multiple ordered subsequences of bit indices that together include the plurality of bit indices. Each bit index was selected from a subsequence based on an order of the bit indices in an ordered sequence that includes all of the bit indices.

As shown at 1554, a method may also involve decoding the received encoded bits, to obtain decoded input bits. The decoding may be referred to as decoding the encoded bits, or decoding the input bits from the encoded bits, for example. The decoding at 1554 may be implemented or performed by a decoder or a processor, for example.

In some embodiments, a decoder might not be a discrete device, but rather a block of logic in silicon or part of a system-on-chip that decodes and uses the decoded input bits. In other embodiments, the decoded input bits are output as shown at 1556, for processing and/or storage, for example.

Any or all of the features that are described herein in the context of encoder-side or transmitter-side methods, with reference to operations at 1500 in FIG. 15, for example, may also apply to or have counterpart features in a decoder-side or receiver-side method. Any one or more of the following features, for example, may be provided or supported, individually or in any of various combinations, in a decoder-side or receiver-side method:
each ordered subsequence may include bit indices of a respective one of multiple different subsets of the bit indices that together include the bit indices of the polar code, with the bit indices in each ordered subsequence being in an order according to the ordered sequence;
each of the different subsets may include a subset of consecutive bit indices in a natural order of the bit indices;
the different subsets may include a subset of non-consecutive bit indices;
the different subsets may include one or more subsets of consecutive bit indices and one or more subsets of non-consecutive bit indices;
each of the different subsets may include a subset of non-consecutive bit indices;
the non-consecutive bit indices may be in an interleaved order;
the different subsets may have been recursively segmented from among the plurality of bit indices;
the ordered subsequence from which each bit index of the first set or the second set is selected may be further based on one or more bit index thresholds;
each threshold of the one or more thresholds may be based on a code length of the polar code, an information block length of the first set of bit indices, and a length of a rate matching output sequence that include the number of the encoded bits received at 1552;
the one or more thresholds include a threshold that is further based on any one or more of: a code rate, a type of rate matching for obtaining the rate matching output sequence, a redundancy version, a decoder type for decoding the encoded bits, an application scenario;
the one or more thresholds may include multiple thresholds, including a threshold based on a target code rate associated with one of the ordered subsequences;
the receiving at 1552 may involve receiving the encoded bits from a first communication device at a second communication device in a wireless communication network.

A method according to another embodiment may involve receiving a number of encoded bits at 1552. The received encoded bits were encoded by obtaining bit indices for placing bit values for encoding by a polar code. As in other embodiments, the bit indices include a first set of bit indices for values of input bits and a second set of bit indices for a predetermined bit value, and each bit index of the first set or the second set has been selected, from an ordered subsequence based on an order of the bit indices in an ordered sequence that includes all of the bit indices. The ordered subsequence is one of multiple ordered subsequences of bit indices that together include all of bit indices.

Such a method may also involve decoding the encoded bits as shown at 1554, to obtain decoded input bits. A method may involve outputting the decoded input bits as well, as shown at 1556.

The ordered sequence may indicate the bit indices in a base order of rank for placing the bit values for encoding by the polar code. A modified ordered sequence from which the bit indices are obtained for the encoding indicates the bit indices in a modified order consistent with each bit index of the first set or the second set being selected, from an ordered subsequence, based on the ordered sequence.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor that is configured, by executing programming for example, to cause the apparatus to perform a method or operations, or to provide or support features, disclosed herein. An apparatus may also include a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to encode input bits by a polar code to obtain a number of encoded bits, and to output the encoded bits. The polar code provides or includes bit indices for placing bit values before encoding, and the bit indices include a first set of bit indices for values of the input bits and a second set of bit indices for a predetermined bit value. Each bit index of the first set or the second set is selected, from one of multiple ordered subsequences of bit indices that together include all of the bit indices, based on an order of the bit indices in an ordered sequence that includes all of the bit indices.

Other embodiments may similarly be implemented using programming that includes instructions to or to cause a processor to: obtain bit indices for placing bit values for encoding by a polar code to obtain a number of encoded bits; encode the input bits by the polar code to obtain the number of encoded bits; and output the encoded bits. The bit indices include a first set and a second set of bit indices, and each bit index of the first set or the second set is selected from an ordered subsequence, as in other embodiments.

Apparatus embodiments are not limited to the foregoing examples of programming-based embodiments. An apparatus may also or instead include, for example, an encoder for encoding input bits by a polar code to obtain a number of encoded bits, and an interface, coupled to the encoder, for outputting the encoded bits. The polar code includes or provides bit indices for placing bit values before the encoding, and the bit indices include a first set of bit indices for values of the input bits and a second set of bit indices for a predetermined bit value. Each bit index of the first set or the second set is selected, from one of multiple ordered subsequences of bit indices that together include all of the bit indices, based on an order of the bit indices in an ordered sequence that includes all of the bit indices.

The apparatus may be a communication device or a component implemented in a communication device. For example, the apparatus implemented in a communication device may be an integrated circuit, which in some contexts may be known by other names, such as chip, modem, modem chip, baseband chip, or baseband processor. In some implementations, one or more integrated circuits can be packaged into a system-on-chip, a system-in-package, or a multi-chip module. The apparatus may comprise one or more integrated circuits or comprise one or more integrated circuits and other discrete components.

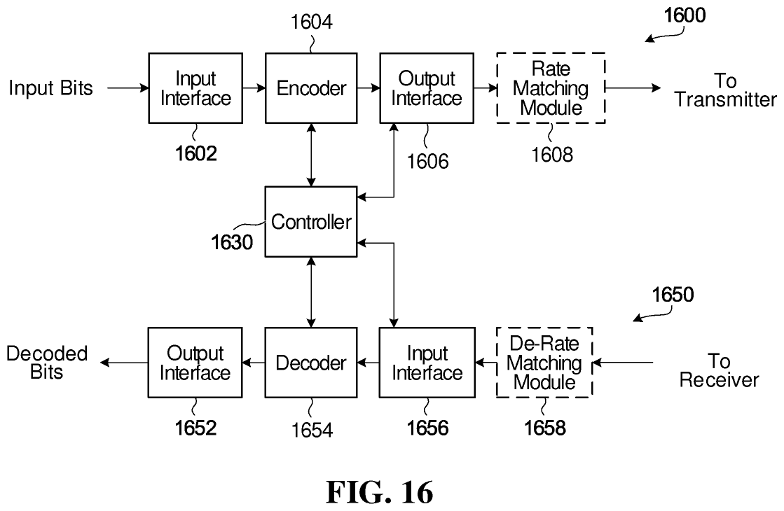

FIG. 16 is a block diagram illustrating an apparatus according to an embodiment. At 1600, FIG. 16 illustrates components of an example apparatus in which or in conjunction with which transmitting and/or encoding features may be implemented, and components of an example apparatus in which or in conjunction with which receiving and/or decoding features may be implemented are illustrated at 1650. A controller 1630 may be provided in either of these types of apparatus. In some embodiments, an apparatus may include both transmitting and receiving features, and either or both of encoding features or decoding features. In the example shown in FIG. 16, an apparatus with all of the illustrated components supports both encoding features and decoding features, as well and transmitting features and receiving features.

For encoding features and transmitting features, the example apparatus in FIG. 16 includes an input interface 1602, an encoder 1604 coupled to the input interface, an output interface 1606, optionally a rate matching module 1608, and a controller 1630 coupled to the encoder and the output interface. The controller 1630 may also or instead be coupled to one or more other components, but connections are not shown in FIG. 16 to avoid congestion in the drawing. Input bits for encoding by the encoder 1604 are shown as inputs to the input interface 1602, and encoded bits are output through the output interface 1606. Although shown as a separate component in FIG. 16, the output interface 1606 for transmitting or otherwise outputting codewords may be provided by, incorporated into, or coupled to the encoder 1604. Similarly, although shown as a separate input interface 1602 in FIG. 16, an interface through which input bits for encoding are obtained by the encoder 1604 may be provided by, incorporated into, or coupled to the encoder.

The rate matching module 1608 may be provided in some embodiments, where rate matching is to be applied to encoded bits prior to transmission for example. A transmitter for transmitting encoded bits, which may be rate-matched encoded bits in some embodiments, is not separately shown in FIG. 16 to avoid congestion in the drawing.

Encode-side or transmit-side features or functions, and other features or functions herein, may be implemented in any of various ways, such as in hardware, firmware, or one or more components that execute software. The present disclosure is not limited to any specific type of implementation, and implementation details may vary between different devices.

Input bits for encoding may be obtained, and encoded bits may be transmitted or otherwise output, via any of various types of interface, including a communication interface in the case of transmitting encoded bits or receiving input bits for encoding. Embodiments are not in any way restricted to any particular type of interface, the implementation of which may be based at least in part on how input bits are to be obtained and how encoded bits are to be output.

In an embodiment, an apparatus includes an encoder such as the encoder 1604 for encoding input bits to generate encoded bits as disclosed herein. An interface may be provided and coupled to an encoder, and in the example shown the output interface 1606 is coupled to the encoder 1604 for outputting the encoded bits.

More generally, an apparatus or a component thereof such as an encoder 1604 or a processor may be configured to encode (or for encoding) input bits to generate or otherwise obtain encoded bits as disclosed herein. An apparatus or a component thereof such as an interface 1606, which may be coupled to the encoder 1604, may be configured to output (or for outputting), or programming may include instructions to output (or for outputting) or to cause a processor to output, the encoded bits as disclosed herein.

Embodiments related to such apparatus or non-transitory computer readable storage media may include any one or more of the following features, for example, which are also discussed elsewhere herein:
each ordered subsequence may include bit indices of a respective one of multiple different subsets of the bit indices that together include all of the bit indices, with the bit indices in each ordered subsequence being in an order according to the ordered sequence; each of the different subsets may include a subset of consecutive bit indices in a natural order of the bit indices;
the different subsets may include a subset of non-consecutive bit indices;
the different subsets may include one or more subsets of consecutive bit indices and one or more subsets of non-consecutive bit indices;
each of the different subsets may include a subset of non-consecutive bit indices;
the non-consecutive bit indices may be in an interleaved order;
the different subsets may be recursively segmented from among the bit indices;
the ordered subsequence from which each bit index of the first set or the second set is selected may be further based on one or more bit index thresholds;
the apparatus or a component thereof such as the encoder 1604 may be configured to determine (or for determining), or programming may include instructions to determine (or for determining), or to cause a processor to determine the ordered subsequence from which each bit index of the first set or the second set is to be selected, based on one or more comparisons involving the one or more bit index thresholds an a respective bit index that is read, in order, from the ordered sequence;
the apparatus or a component thereof such as the encoder 1604 or a comparator coupled to the encoder may be configured to compare (or for comparing), or programming may include instructions to compare (or for comparing), or to cause a processor to compare the one or more bit index thresholds with a respective bit index that is read, in order, from the ordered sequence;
the apparatus or a component thereof such as the encoder 1604 may be configured to select (or for selecting), or programming may include instructions to select (or for selecting), or to cause a processor to select each bit index from the determined ordered subsequence from which each bit index is to be selected;
each of the ordered subsequences may indicate the bit indices in the ordered subsequence in an order of rank for placing the bit values for encoding by the polar code;
the selecting may involve selecting, from the determined ordered subsequence: a next bit index in decreasing order of rank from the determined ordered subsequence as a bit index of the first set; or a next bit index in increasing order of rank from the determined ordered subsequence as a bit index of the second set;
each threshold of the one or more thresholds may be based on a code length of the polar code, an information block length of the first set of bit indices, and a length of a rate matching output sequence;
the apparatus or a component thereof such as the encoder 1604 or a rate matching module such as 1608 coupled to the encoder may be configured to perform (or for performing), or programming may include instructions to perform (or for performing), or to cause a processor to perform rate matching to obtain the rate matching output sequence;
the one or more thresholds may include a threshold that is further based on any one or more of: a code rate, a type of rate matching for obtaining the rate matching output sequence, a redundancy version, a decoder type for decoding the encoded bits, an application scenario;
the one or more thresholds may include multiple thresholds, including a threshold based on a target code rate associated with one of the ordered subsequences;
the apparatus or a component thereof such as the encoder 1604, the interface 1606, or a transmitter coupled to the interface 1606, may be configured to transmit (or for transmitting), or programming may include instructions to transmit (or for transmitting), or to cause a processor to transmit the encoded bits from a first communication device to a second communication device in a wireless communication network;
the apparatus or a component thereof such as the encoder 1604, the interface 1606, or a transmitter coupled to the interface 1606, may be configured to transmit (or for transmitting), or programming may include instructions to transmit (or for transmitting), or to cause a processor to transmit the rate matching output sequence from a first communication device to a second communication device in a wireless communication network.

According to another embodiment, an apparatus includes an encoder such as the encoder 1604 for obtaining bit indices of a polar code, and for encoding bit values placed on the bit indices by the polar code to obtain a number of encoded bits. Such an apparatus may also include an interface such as the output interface 1606, coupled to the encoder, for outputting the encoded bits. As in other embodiments, the bit indices include a first set of bit indices for values of input bits and a second set of bit indices for a predetermined bit value, and each bit index of the first set or the second set selected, from an ordered subsequence, based on an order of the bit indices in an ordered sequence.

The ordered sequence may indicate the bit indices in a base order of rank for placing the bit values for encoding by the polar code. Obtaining the bit indices by the encoder may then involve modifying the ordered sequence to obtain a modified ordered sequence indicating the bit indices in a modified order, and obtaining the first set of bit indices and the second set of bit indices from the modified ordered sequence. The modified order is consistent with each bit index of the first set or the second set being selected, from one of the multiple ordered subsequences, based on the ordered sequence.

With reference again to FIG. 16, the example apparatus also includes components to provide or support receiving and decoding features. These components may be provided separately in a decoding or receiving device, or together with other components to provide or support decoding or receiving features together with encoding or transmitting features.

An input interface 1656 is coupled to a decoder 1654, and these components are also coupled to the controller 1630, which as described at least above may also or instead be coupled to one or more other components. The decoder 1654 is coupled to an output interface 1652. FIG. 16 also illustrates decoded bits, which may also be referred to as decoded input bits or recovered input bits, as outputs from the output interface 1652. Encoded bits are inputs received by the interface 1656. The interface 1656 may be provided by, incorporated into, or coupled to the decoder 1654, and similarly an interface 1652 through which decoded bits are output by the decoder may be provided by, incorporated into, or coupled to the decoder. In embodiments that involve rate matching, a de-rate matching module 1658 may be provided to implement counterpart receive-side features of transmit-side rate matching.

Decode-side or receive-side features or functions, and other features or functions herein, may be implemented in any of various ways, such as in hardware, firmware, or one or more components that execute software. The present disclosure is not limited to any specific type of implementation, and implementation details may vary between different devices, for example.

Encoded bits may be received or otherwise obtained, and decoded bits may be output, via any of various types of interface, including a communication interface in the case of receiving encoded bits or transmitting decoded bits. Embodiments are not in any way restricted to any particular type of receiver or interface, the implementation of which may be based at least in part on how encoded bits for decoding are to be obtained and how decoded bits are to be output.

Encoder and decoder interfaces are shown separately in FIG. 16 to illustrate that encoding and decoding features may be implemented independently. However, it should be appreciated that a single device or equipment may support both encoding and decoding, in which case an encoder and a decoder may be coupled to the same interface(s) at 1602, 1652. For example, the encoder 1604 and the decoder 1654 may be coupled to the same interface(s) to obtain input bits for encoding by the encoder and to output decoded bits from the decoder. The encoder 1604 and the decoder 1654 may also or instead be coupled to the same interface(s) to output encoded bits that are generated by the encoder and receive encoded bits for decoding by the decoder.

In an embodiment, an apparatus includes an interface such as the interface 1656 for receiving a number of encoded bits encoded by a polar code, and a decoder such as the decoder 1654, coupled to the interface, for decoding the encoded bits to obtain decoded input bits. The polar code includes or provides bit indices for placing bit values before encoding, and the bit indices include a first set of bit indices for values of input bits and a second set of bit indices for a predetermined bit value. Each bit index of the first set or the second set has been selected from an ordered subsequence as disclosed herein.

More generally, an apparatus or a component thereof such as an interface 1656 or a receiver may be configured to receive (or for receiving) or to otherwise obtain (or for obtaining), or programming may include instructions to receive (or for receiving) or to otherwise obtain (or for obtaining) or to cause a processor to receive or otherwise obtain encoded bits. Such an apparatus or a component thereof such as a decoder 1654 or a processor may be configured to decode (or for decoding), or programming may include instructions to decode (or for decoding) the encoded bits.

Embodiments related to such apparatus or non-transitory computer readable storage media may include any one or more of the following features, for example, which are also discussed elsewhere herein:
each ordered subsequence may include bit indices of a respective one of multiple different subsets of the bit indices that together include all of the bit indices, with the bit indices in each ordered subsequence being in an order according to the ordered sequence;
each of the different subsets may include a subset of consecutive bit indices in a natural order of the bit indices;
the different subsets may include a subset of non-consecutive bit indices;
the different subsets may include one or more subsets of consecutive bit indices and one or more subsets of non-consecutive bit indices;
each of the different subsets may include a subset of non-consecutive bit indices;
the non-consecutive bit indices may be in an interleaved order;
the different subsets may have been recursively segmented from among the bit indices;
the ordered subsequence from which each bit index of the first set or the second set is selected may be further based on one or more bit index thresholds;
each threshold of the one or more thresholds may be based on a code length of the polar code, an information block length of the first set of bit indices, and a length of a rate matching output sequence that includes the number of the encoded bits;
the apparatus or a component thereof such as the decoder 1654, the interface 1656, a de-rate matching module 1658 coupled to the decoder or the interface, or a receiver coupled to the decoder or the interface, may be configured to perform (or for performing), or programming may include instructions to perform (or for performing), or to cause a processor to perform counterpart de-rate matching of transmit-side rate matching that obtained the rate matching output sequence;
the one or more thresholds may include a threshold that is further based on any one or more of: a code rate, a type of rate matching for obtaining the rate matching output sequence, a redundancy version, a decoder type for decoding the encoded bits, an application scenario;
the one or more thresholds include multiple thresholds, including a threshold based on a target code rate associated with one of the ordered subsequences;
the receiving may involve receiving the encoded bits from a first communication device at a second communication device in a wireless communication network.

According to another embodiment, an apparatus includes an interface such as the interface 1656 for receiving a number of encoded bits that have been encoded by obtaining bit indices. The bit indices are for placing bit values for encoding by a polar code. Such an apparatus may also include a decoder such as the decoder 1654, coupled to the interface, for decoding the encoded bits to obtain decoded input bits. As in other embodiments, the bit indices include a first set of bit indices for values of input bits and a second set of bit indices for a predetermined bit value, and each bit index of the first set or the second set selected, from an ordered subsequence, based on an order of the bit indices in an ordered sequence.

More generally, an apparatus or a component thereof such as an interface 1656 or a receiver may be configured to receive (or for receiving) or to otherwise obtain (or for obtaining), or programming may include instructions to receive (or for receiving) or to otherwise obtain (or for obtaining) or to cause a processor to receive or otherwise obtain encoded bits. Such an apparatus or a component thereof such as a decoder 1654 or a processor may be configured to decode (or for decoding), or programming may include instructions to decode (or for decoding) the encoded bits.

The ordered sequence may indicate the bit indices in a base order of rank for placing the bit values for encoding by the polar code. A modified ordered sequence from which the indices are obtained may indicate the bit indices in a modified order consistent with each bit index of the first set or the second set being selected, from an ordered subsequence as disclosed herein, based on the ordered sequence.

Other features disclosed herein may also or instead be provided or supported in apparatus embodiments.

Apparatus embodiments are not in any way restricted to single devices. A system, for example, may include a first communication device and a second communication device. The first communication device may be configured to transmit a number of encoded bits that have been encoded by a polar code. The polar code includes or provides bit indices for placing bit values before encoding, and the bit indices include a first set of bit indices for values of input bits and a second set of bit indices for a predetermined bit value. Each bit index of the first set or the second set is selected, from one of multiple ordered subsequences of bit indices that together include all of the bit indices, based on an order of the bit indices in an ordered sequence that includes all of the bit indices. The second communication device may be configured to receive the encoded bits from the first communication device, and to decode the encoded bits to obtain decoded input bits.

More generally, other features disclosed herein may also or instead be provided in method, apparatus, and/or system embodiments.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

The following acronyms, abbreviations, and initialisms may be used herein:

| | Acronym/ |
|---|---|
| | Abbreviation/ |
| Full Name | Initialism |
| Long Term Evolution | LTE |
| New Radio | NR |
| Forward error correction | FEC |
| Multiple Access | MA |
| Quality of Service | QoS |
| low-density parity check codes | LDPC |
| cyclic redundancy check | CRC |
| Parity check | PC |
| ultra-reliable low latency | uRLLC |
| communications | |
| Enhanced mobile broadband | eMBB |
| massive Machine Type | mMTC |
| Communications | |
| non-terrestrial networks | NTN |
| Internet of Things | IoT |
| Bit Error Rate | BER |
| Block Error Rate | BLER |
| Packet Error Rate | PER |
| Spectral Efficiency | SE |
| Hybrid automatic repeat request | HARQ |
| Incremental-redundancy HARQ | IR-HARQ |
| Channel Quality Indicator | CQI |
| Modulation Coding Scheme | MCS |
| gNodeB or 5G base station | gNB |
| user equipment | UE |
| Radio Resource Control | RRC |
| Radio Network Temporary Identifier | RNTI |
| Uplink Control Information | UCI |
| Downlink Control Information | DCI |
| Physical Broadcast Channel | PBCH |
| Half-radio frame bit | HRF |
| Synchronization Signal Block | SSB |
| unequal error protection | UEP |
| variable node | VN |
| check node | CN |
| Log-likelihood ratio | LLR |
| Successive cancellation | SC |
| Successive cancellation list | SCL |
| CRC-aided successive | CA-SCL |
| cancellation list | |
| Parity-check successive | PC-SCL |
| cancellation list | |

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

What is claimed is:

1. A method comprising:
encoding input bits by a polar code to obtain a number of encoded bits; and
outputting the encoded bits;
the polar code comprising a plurality of bit indices for placing bit values before the encoding, the plurality of bit indices comprising a first set of bit indices for values of the input bits and a second set of bit indices for a predetermined bit value, and
each bit index of the first set or the second set selected, from an ordered subsequence of a plurality of ordered subsequences of bit indices that together include the plurality of bit indices, based on an order of the plurality of bit indices in an ordered sequence that includes the plurality of bit indices.

2. The method of claim 1, wherein each ordered subsequence of the plurality of ordered subsequences comprises bit indices of a respective one of a plurality of different subsets of the bit indices that together comprise the plurality of bit indices, the bit indices in each ordered subsequence being in an order according to the ordered sequence.

3. The method of claim 2, wherein each of the different subsets comprises a subset of consecutive bit indices in a natural order of the bit indices.

4. The method of claim 2, wherein the plurality of different subsets comprises a subset of non-consecutive bit indices.

5. The method of claim 4, wherein the non-consecutive bit indices are in an interleaved order.

6. A method comprising:
receiving a number of encoded bits encoded by a polar code; and
decoding the encoded bits to obtain decoded input bits,
the polar code comprising a plurality of bit indices for placing bit values for encoding, the plurality of bit indices comprising a first set of bit indices for values of input bits and a second set of bit indices for a predetermined bit value, and
each bit index of the first set or the second set having been selected, from an ordered subsequence of a plurality of ordered subsequences of bit indices that together include the plurality of bit indices, based on an order of the plurality of bit indices in an ordered sequence that includes the plurality of bit indices.

7. The method of claim 6, wherein each ordered subsequence of the plurality of ordered subsequences comprises bit indices of a respective one of a plurality of different subsets of the bit indices that together comprise the plurality of bit indices, the bit indices in each ordered subsequence being in an order according to the ordered sequence.

8. The method of claim 7, wherein each of the different subsets comprises a subset of consecutive bit indices in a natural order of the bit indices.

9. The method of claim 7, wherein the plurality of different subsets comprise a subset of non-consecutive bit indices.

10. The method of claim 9, wherein the non-consecutive bit indices are in an interleaved order.

11. An apparatus comprising:
at least one processor; and
memory coupled to the at least one processor and storing instructions that, when executed by the at least one processor, cause the apparatus to perform operations including:
encoding input bits by a polar code to obtain a number of encoded bits; and
outputting the encoded bits,
the polar code comprising a plurality of bit indices for placing bit values before the encoding, the plurality of bit indices comprising a first set of bit indices for values of the input bits and a second set of bit indices for a predetermined bit value, and
each bit index of the first set or the second set selected, from an ordered subsequence of a plurality of ordered subsequences of bit indices that together include the plurality of bit indices, based on an order of the plurality of bit indices in an ordered sequence that includes the plurality of bit indices.

12. The apparatus of claim 11, wherein each ordered subsequence of the plurality of ordered subsequences comprises bit indices of a respective one of a plurality of different subsets of the bit indices that together comprise the plurality of bit indices, the bit indices in each ordered subsequence being in an order according to the ordered sequence.

13. The apparatus of claim 12, wherein each of the different subsets comprises a subset of consecutive bit indices in a natural order of the bit indices.

14. The apparatus of claim 12, wherein the plurality of different subsets comprises a subset of non-consecutive bit indices.

15. The apparatus of claim 14, wherein the non-consecutive bit indices are in an interleaved order.

16. An apparatus comprising:
at least one processor; and
memory coupled to the at least one processor and storing instructions that, when executed by the at least one processor, cause the apparatus to perform operations including:
receiving a number of encoded bits encoded by a polar code; and
decoding the encoded bits to obtain decoded input bits,
the polar code comprising a plurality of bit indices for placing bit values for encoding, the plurality of bit indices comprising a first set of bit indices for values of input bits and a second set of bit indices for a predetermined bit value, and
each bit index of the first set or the second set having been selected, from an ordered subsequence of a plurality of ordered subsequences of bit indices that together include the plurality of bit indices, based on an order of the plurality of bit indices in an ordered sequence that includes the plurality of bit indices.

17. The method of claim 16, wherein each ordered subsequence of the plurality of ordered subsequences comprises bit indices of a respective one of a plurality of different subsets of the bit indices that together comprise the plurality of bit indices, the bit indices in each ordered subsequence being in an order according to the ordered sequence.

18. The method of claim 17, wherein each of the different subsets comprises a subset of consecutive bit indices in a natural order of the bit indices.

19. The method of claim 17, wherein the plurality of different subsets comprise a subset of non-consecutive bit indices.

20. The method of claim 19, wherein the non-consecutive bit indices are in an interleaved order.
